(19) United States
(12) Patent Application Publication
(10) Pub. No.: US 2025/0174539 A1
(43) Pub. Date: May 29, 2025

(54) 3D INTEGRATED CIRCUIT PACKAGE AND SUBSTRATE STRUCTURE THEREOF

(71) Applicants: ND-HI TECHNOLOGIES LAB, INC., TAIPEI CITY (TW); ETRON TECHNOLOGY, INC., HSINCHU (TW)

(72) Inventors: HO-MING TONG, TAIPEI CITY (TW); CHIH-HSUN HSIEH, TAIPEI CITY (TW); WEI YEN, TAIPEI CITY (TW); CHAO-CHUN LU, HSINCHU (TW)

(21) Appl. No.: 18/963,300

(22) Filed: Nov. 27, 2024

Related U.S. Application Data
(60) Provisional application No. 63/603,654, filed on Nov. 29, 2023.
(60) Provisional application No. 63/603,650, filed on Nov. 29, 2023.
(60) Provisional application No. 63/603,652, filed on Nov. 29, 2023.
(60) Provisional application No. 63/635,644, filed on Apr. 18, 2024.

(51) Int. Cl. H01L 23/498; H01L 21/48; H01L 23/00; H01L 23/13; H01L 23/14; H01L 23/367; H01L 23/373; H01L 23/528; H01L 23/538; H01L 25/18; H05K 1/18; H10B 80/00

(52) U.S. Cl. CPC H01L 23/49833; H01L 23/13; H01L 23/14; H01L 23/3672; H01L 23/373; H01L 23/5381; H01L 21/4846; H01L 23/3675; H01L 23/5286; H01L 24/13; H01L 24/14; H01L 24/16; H01L 24/30; H01L 24/32; H01L 24/73; H01L 25/18; H01L 2224/13147; H01L 2224/1403; H01L 2224/16225; H01L 2224/3003; H01L 2224/32225; H01L 2224/73204; H01L 2224/73253; H01L 2924/1431; H01L 2924/14361; H05K 1/189; H10B 80/00

(57) ABSTRACT

A 3D integrated circuit package is provided. The 3D integrated circuit package includes a substrate structure having a first surface and a second surface opposite to the first surface, a high-power die over the substrate structure, a lower-power die over the high-power die, a first interposer between the first surface of the substrate structure and the high-power die, and a second interposer between the high-power die and the lower-power die. The substrate structure includes a thermal enhancement portion located under the high-power die, and at least one of a thermal conductivity or a geometry of the thermal enhancement portion is different from other portions of the substrate structure. A substrate structure of the 3D integrated circuit package is also provided.

### PRIORITY CLAIM AND CROSS-REFERENCE

This application claims the benefit of prior-filed U.S. provisional application No. 63/603,654, filed on Nov. 29, 2023, prior-filed U.S. provisional application No. 63/603,650, filed on Nov. 29, 2023, prior-filed U.S. provisional application No. 63/603,652, filed on Nov. 29, 2023, and prior-filed U.S. provisional application No. 63/635,644, filed on Apr. 18, 2024, and incorporates by reference herein in its entirety.

### FIELD

This disclosure relates in general to a three dimensional (3D) integrated circuit package and a substrate structure, and more particularly, the 3D integrated circuit package includes the structure feature for heat dissipation. The substrate structure may fulfill the heat dissipation mechanism in the 3D integrated circuit package.

### BACKGROUND

This disclosure intends to mitigate three classic problems in computing: (1) memory wall; (2) I/O wall and (3) lateral power delivery and power wall while providing unprecedented energy efficiency by stacking memory on processor in the vertical (or package thickness) direction in conjunction with the incorporation of photonic I/Os and vertical power delivery networks using state-of-the-art high bandwidth memory (HBM) DRAM stacks (e.g., HBM3s) and GPU (e.g., Nvidia's H100 that powers ChatGPT or equivalently its next-generation products) for illustration for applications such as high-performance computing (HPC), data centers and AI (artificial intelligence).

A memory wall may refer to the situation where the performance bottleneck occurs when the speed of a processor exceeds the speed of memory access. This technical issue arises in the development of advanced memory structure, where the processor's ability to execute instructions quickly is hindered by the slow speed of accessing data from memory. This physical barrier may limit the development of AI technology, as the processor may spend a significant amount of time waiting to retrieve data from memory, and is unable to fully utilize the processing power, resulting in overall system performance degradation.

The transfer speed of input/output (I/O) can also potentially be another bottleneck limiting computing performance. When the transfer speed between the processor and memory is slower than the processor's computing speed, the processor will be affected with its performance degraded due to the delays in data transfer.

The power wall refers to a limit on the clock speed of processors due to the amount of power consumed and the resulting heat dissipation. The switching power (P) dissipated by a chip is proportional to capacitance (C), voltage squared (V²), and frequency (f). Therefore, the higher the frequency at which the processor operates, the more power it consumes and the more heat it generates. It is not solely a matter of chips being too hot if they were clocked at higher frequencies. The term “wall” actually refers to a combination of factors that limit a processor's performance, including power consumption, heat dissipation, and other technological constraints. These factors can make it difficult or impossible to continue increasing the clock speed, leading to a “wall” that limits the processor's performance.

Referring to FIG. 1, in the past two decades or so (i.e., 1990s to 2023), the scaling of peak hardware floating point operations per second (FLOPS), and memory/interconnect bandwidth have continued undaunted. In this time period, the peak hardware FLOPS has grown by about 60,000 times (an average of three times every two years) while the bandwidth of DRAM has grown by about 100 times (an average of 1.6 times every two years), and the interconnect bandwidth has grown by about 30 times (an average of 1.4 times every two years)—please refer to Silicon Matter, “The Memory Wall and Its Implications,” Mar. 16, 2024.

Despite the phenomenal progress made in the past few decades in processor and memory, a processor runs much faster than the speed at which memory chips can provide data and the performance gap between the processor and memory continues to widen.

This widening performance gap created by the above memory wall (which refers to the physical barriers that are limiting how fast data can be moved between a system's memory and processor) leads to a situation where processors such as GPUs and CPUs spend a significant amount of time waiting and idling for data to be delivered from the memory, thereby significantly impacting system performance, especially for tasks that require large amounts of data to be processed quickly and simultaneously, such as running complex AI algorithms. In fact, the memory wall is quickly becoming a large issue for AI applications since AI accelerators (such as the world's current most advanced GPU, Nvidia® H100 in 2.5D IC) are specially designed for efficient, high-speed parallel processing of massive amounts of data.

As shown in FIG. 1, which shows the bandwidth scaling of different generations of memory, interconnects and CPUs/GPUs. As you can see, the hardware FLOPs, and the DRAM bandwidth and the interconnect bandwidth continue to widen. This performance discrepancy coupled with power usage severely compromise processor efficiency. These bottlenecks cause expensive Nvidia® H100 GPUs to become underutilized, highlighting a critical efficiency in running various AI algorithms and large language models on them.

Resorting to liquid cooling for thermal management, this disclosure proposes to package 6 HBM3s and GPU in the vertical or package thickness direction (i.e., the z direction) to dramatically mitigate the memory wall and bandwidth issues as vertical stacking (1) greatly shortens the distances of data transfer between the processor and the memory, (2) provides a far higher bus width/interconnect bandwidth due to a far higher number of data paths that can be created between the processor and the memory, (3) speeds up data transfer between the processor and the memory, (4) significantly reduces power and energy consumption and (5) enables far higher processor power (while keeping other conditions the same), compared to its 2.5D IC counterpart which is used in packaging H100 and 6 HBM2Es (or 6 HBM3s) today. Previous studies have shown that every time data is transferred back and forth across the memory bus, accessing DRAM requires approximately 60 pico-joules for each byte, which is a thousand-fold more energy than processing the data that requires 50-60 femto-joules per computational operation. 3D IC stacking helps minimize the required energy consumption due to higher bandwidths and the short distances data has to travel.

It is worth noting in passing that stacking a high power GPU (e.g., at 700 W/chip today for Nvidia® H100 and can be greater than about 2,000 W/chip in the future) with the HBMs in the vertical direction will inadvertently overheat the high power GPU and HBMs way beyond their maximum operating temperatures (e.g., about 120° C.). To remedy this thermal issue, some companies are attempting to use IC-package-system co-design, thermal vias, thermal planes and/or thermal bumps. This approach, however, has limitations in terms of the maximum GPU power it can handle. In this configuration, at a GPU power of 1,500 W/chip, the GPU can overheat to over 250° C., even with the use of liquid cooling according to some simulations. The incorporation of copper hybrid bonds is not expected to alleviate the overheating problem.

### SUMMARY

It is one aspect of the present disclosure to provide a 3D integrated circuit package. The 3D integrated circuit package includes a substrate structure having a first surface and a second surface opposite to the first surface, a high-power die over the substrate structure, a lower-power die over the high-power die, a first interposer between the first surface of the substrate structure and the high-power die, and a second interposer between the high-power die and the lower-power die. The substrate structure includes a thermal enhancement portion located under the high-power die, and at least one of a thermal conductivity or a geometry of the thermal enhancement portion is different from other portions of the substrate structure.

It is another aspect of the present disclosure to provide a 3D integrated circuit package. The 3D integrated circuit package includes a substrate structure having a first surface and a second surface opposite to the first surface, a lower-power die over the substrate structure, a first high-power die over the lower-power die, a first interposer between the first surface of the substrate structure and the lower-power die, and a second interposer between the first high-power die and the lower-power die. The substrate structure includes a thermal enhancement portion located under the first high-power die, and at least one of a thermal conductivity or a geometry of the thermal enhancement portion is different from other portions of the substrate structure.

It is yet another aspect of the present disclosure to provide a substrate structure. The substrate structure includes a plurality of substrate units separated from each other, and a bridge structure configured to electrically connect adjacent substrate units. The bridge structure includes a first side and a second side opposite to the first side, at least one of the first side or the second side is electrically connected to adjacent substrate units or an integrated circuit through copper pillar micro-bumps or an interconnect layer such as copper hybrid bonds.

### BRIEF DESCRIPTION OF THE DRAWINGS

Aspects of the present disclosure are best understood from the following detailed description when read with the accompanying figures. It is noted that, in accordance with the standard practice in the industry, various structures are not drawn to scale. In fact, the dimensions of the various structures may be arbitrarily increased or reduced for clarity of discussion.

FIG. 1 illustrates a scaling of peak hardware FLOPs, and memory/interconnect bandwidth.

FIG. 2 illustrates a cross-sectional view of a 2.5D IC structure, according to some comparative embodiments.

FIG. 3 illustrates a cross-sectional view of a 3D IC structure, according to some embodiments of the present disclosure.

FIG. 4 illustrates a cross-sectional view of a 3D IC structure, according to some embodiments of the present disclosure.

FIG. 5A illustrates a cross-sectional view of a 3D IC structure, according to some embodiments of the present disclosure.

FIG. 5B illustrates a cross-sectional view of a 3D IC structure, according to some embodiments of the present disclosure.

FIG. 5C illustrates a cross-sectional view of a 3D IC structure with a heat sink, according to some embodiments of the present disclosure.

FIG. 6 illustrates a three-dimensional diagram of a substrate structure, according to some embodiments of the present disclosure.

FIG. 7 illustrates a simulation result of liquid immersion cooled 3D IC structures, according to some embodiments of the present disclosure.

FIG. 8 illustrates a simulation result of liquid immersion cooled 3D IC structures, according to some embodiments of the present disclosure.

FIG. 9 illustrates a cross-sectional view of a 3D IC structure, according to some embodiments of the present disclosure.

FIG. 10 illustrates a cross-sectional view of a 3D IC structure with a heat spreader, according to some embodiments of the present disclosure.

FIG. 11 illustrates a cross-sectional view of a 3D IC structure with a heat spreader, according to some embodiments of the present disclosure.

FIG. 12 illustrates a cross-sectional view of a 3D IC structure with a heat spreader, according to some embodiments of the present disclosure.

FIG. 13 illustrates a cross-sectional view of a liquid immersion cooled 3D IC structure, according to some embodiments of the present disclosure.

FIG. 14 illustrates a cross-sectional view of an enhanced 2.5D IC structure with a heat spreader, according to some embodiments of the present disclosure.

FIG. 15 illustrates a cross-sectional view of an enhanced 2.5D IC structure with a heat spreader, according to some embodiments of the present disclosure.

FIGS. 16A and 16B illustrate cross-sectional views of a composite interposer, according to some embodiments of the present disclosure.

FIG. 16C illustrates a cross-sectional view of a 3D IC structure with composite interposers, according to some embodiments of the present disclosure.

FIGS. 17A to 17F illustrates cross-sectional views of a process of manufacturing a composite interposer, according to some embodiments of the present disclosure.

FIG. 18A illustrates a cross-sectional view of a 3D IC structure, according to some embodiments of the present disclosure.

FIG. 18B illustrates a cross-sectional view of a 3D IC structure, according to some embodiments of the present disclosure.

FIG. 19A illustrates a cross-sectional view of a 3D IC structure, according to some embodiments of the present disclosure.

FIG. 19B illustrates a cross-sectional view of a 3D IC structure, according to some embodiments of the present disclosure.

FIG. 20A illustrates a top view of a portion of a 3D IC structure, according to some embodiments of the present disclosure.

FIG. 20B illustrates a side view of a portion of a 3D IC structure, according to some embodiments of the present disclosure.

FIG. 21A illustrates a cross-sectional view of a substrate structure, according to some embodiments of the present disclosure.

FIG. 21B illustrates a cross-sectional view of a substrate structure, according to some embodiments of the present disclosure.

FIGS. 22A to 22C illustrate cross-sectional views of a substrate structure with a flexible circuit, according to some embodiments of the present disclosure.

FIG. 23 illustrates a cross-sectional view of a substrate structure with a hybrid bridge, according to some embodiments of the present disclosure.

FIGS. 24A to 24C illustrate cross-sectional views of a substrate structure with an edge connection bridge, according to some embodiments of the present disclosure.

FIGS. 25A to 25E illustrate cross-sectional views of a process of manufacturing a substrate structure with an edge connection bridge, according to some embodiments of the present disclosure.

FIG. 26A illustrates a cross-sectional view of a substrate structure with a dual-sided bridge, according to some embodiments of the present disclosure.

FIG. 26B illustrates a cross-sectional view of a substrate structure with a dual-sided bridge, according to some embodiments of the present disclosure.

FIGS. 27A to 27D illustrate cross-sectional views of the locations of electronic device in 3D IC structures, according to some embodiments of the present disclosure.

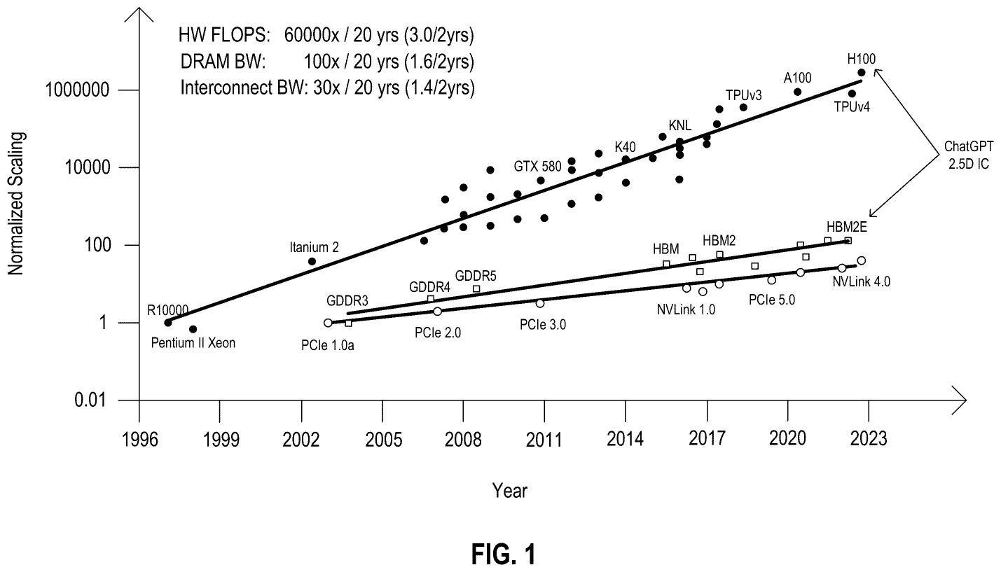

In the following detailed description, for purposes of explanation, numerous specific details are set forth in order to provide a thorough understanding of the disclosed embodiments. It will be apparent, however, that one or more embodiments may be practiced without these specific details. In other instances, well-known structures and devices are schematically shown in order to simplify the drawings.

### DETAILED DESCRIPTION

The following disclosure provides many different embodiments, or examples, for implementing different features of the provided subject matter. Specific examples of elements and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper”, “on” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

As used herein, the terms such as “first”, “second” and “third” describe various elements, components, regions, layers and/or sections, these elements, components, regions, layers and/or sections should not be limited by these terms. These terms may be only used to distinguish one element, component, region, layer, or section from another. The terms such as “first”, “second”, and “third” when used herein do not imply a sequence or order unless clearly indicated by the context.

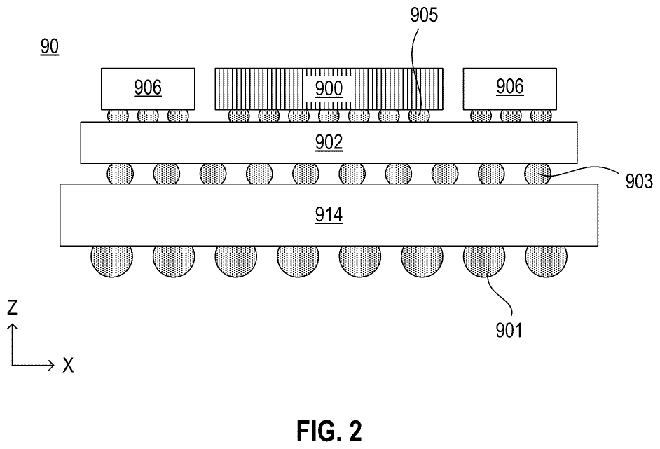

Referring to FIG. 2, which illustrates a 2.5D integrated circuit (IC) structure in some comparative embodiments. As shown in the figure, the 2.5D IC structure 90 includes a substrate 914 utilized as a carrier. A plurality of ball grid array (BGA) balls 901 may be in contact with a side of the substrate 914. A silicon interposer 902 is bonded over the substrate 914 through a plurality of solder bumps 903. Over the silicon interposer 902, a plurality of HBMs 906 and a logic IC such as a GPU 900 can be mounted on the upper side of the silicon interposer 902. The HBMs 906 and the GPU 900 can electrically connect to the silicon interposer 902 through a plurality of micro-bumps 905 or solder bumps. In the comparative embodiments, the GPU 900 can be cooled by attaching a heat spreader, (HS, or a vapor chamber) to the backside of the GPU and a cold plate to the HS, i.e., by direct-to-chip (DtC) liquid cooling. Alternatively, the GPU can be cooled using a finned structure (such as a silicon based HS containing micro-fins bonded to the backside of the GPU with the finned structure cooled directly by an impinging liquid coolant flow. This cooling mechanism is capable of dissipating heat at greater than 6.8 W/mm².

To achieve more efficient heat dissipation for 3D ICs containing high-power processors and HBMs, some embodiments of the present disclosure provide 3D IC structures that may include different heat dissipation or spreading structures suitable for one or more cooling methods with better heat dissipation efficiency than direct-to-chip liquid cooling. The structures and or part of them disclosed herein for 3D ICs may also find some utilities for next-generation 2.5D ICs and hybrid 2.5D/3D structures involving higher-power processors and memory devices involving the stacking a multiplicity of processors with memory devices in the z direction. Some embodiments of the present disclosure aim to resolve or significantly alleviate the overheating issues in 2.5D and 3D ICs embodying logic devices (e.g., GPUs, CPUs, neural network processing units (NPUs), tensor processing units (TPUs), etc.) and memory devices (e.g., HBMs) for high-performance computing, data centers and AI computing.

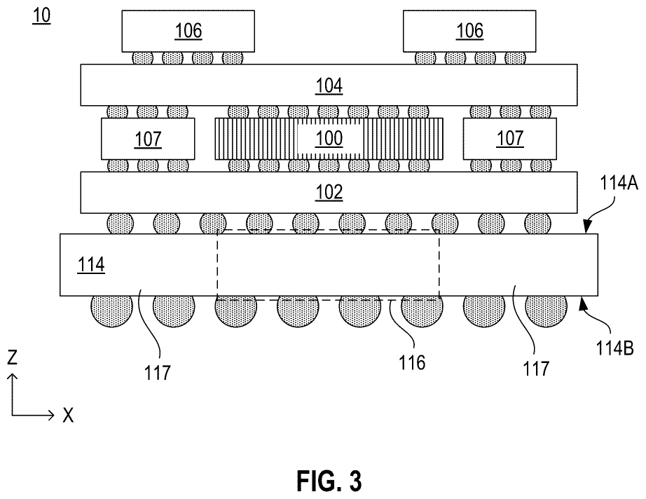

Referring to FIG. 3, in some embodiments, the 3D IC structure 10 includes a substrate structure 114 having a first surface 114A and a second surface 114B opposite to the first surface 114A. A high-power die 100 is disposed over the substrate structure 114. In some embodiments, the high-power die 100 is a logic device such as GPUs, CPUs, NPUs, TPUs, etc. The logic device can be an IC chip, or a combination of chiplets. One or more lower-power dies 106 are disposed over the high-power die 100. In some embodiments, the lower-power die 106 is a memory device such as a HBM. In some embodiments, the lower-power die 106 can be a passive device (e.g., a deep-trench capacitor), an active device such as an integrated voltage regulator or a lower-power processor, or an optical device such as an optical I/O.

A first interposer 102 is disposed between the first surface 114A of the substrate structure 114 and the high-power die 100. A second interposer 104 is disposed between the high-power die 100 and the lower-power die 106. In some embodiments, one or both of the first and second interposers, 102 and 104, can be used for heat spreading, or at least substantially provide a cooling effect. For example, in the 3D IC structure 10 shown in FIG. 3, the high-power die 100 is sandwiched by the first interposer 102 and the second interposer 104, while the first interposer 102 and the second interposer 104 can be made of a high-thermal-conductivity (HTC) material such as diamond with a thermal conductivity (TC) of >1,500 W/m·K and be used for heat dissipation to ensure that the processor and HBMs in the 3D ICs are not overheated and more importantly, the 3D ICs can support the use of higher-power processors for higher performance. Furthermore, in order to design in appropriate heat spreading capabilities of the first interposer 102 and the second interposer 104 for performance, cost and time-to-market (TTM), the TCs of the two interposers can be selected from a wide arrange of materials from diamond (with a TC of >1,500 W/m·K for polycrystalline diamond) to glass (with a TC of around 1 W/m·K), depending on the particular 2.5D IC, 3D IC or 2.5D/3D hybrid structure, higher-power processor locations and thermal design power (TDP) in question.

For instance, in some embodiments, the high-power die 100 is cooled under a dual-sided cooling topology wherein the first interposer 102 and the second interposer 104 are both made of HTC, low-coefficient-of-thermal-expansion (LCTE) interposers. The high-HTC materials used in forming the two interposers can be the same material or different materials. In some embodiments, the thermal conductivities of the first interposer 102 and the second interposer 104 are substantially greater than about 1,500 W/m·K such as ≥2,000 W/m·K for single crystal diamond which is the highest of all known materials on Earth

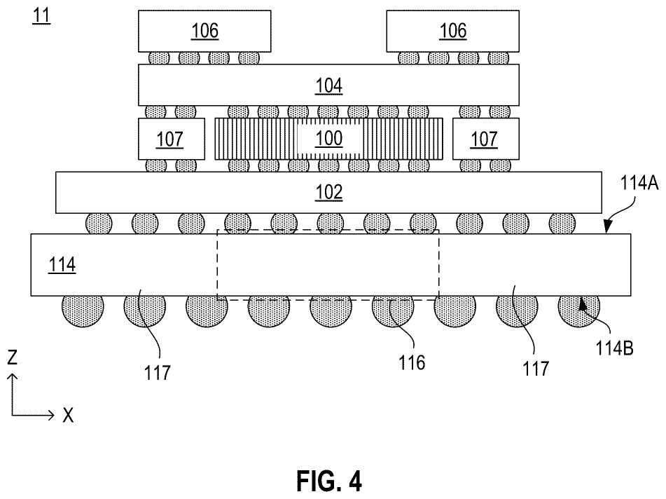

In some embodiments, the thermal conductivity of the second interposer 104 is lower than that of the first interposer 102. For instance, the thermal conductivity of the second interposer 104 can be lower than about 1,500 W/m·K (e.g., down to about 1 W/m·K for glass), whereas as the thermal conductivity of the first interposer 102 is greater than 1,500 W/m·K. Besides their TCs, the heat spreading capabilities of these interposers also are dependent upon interposer sizes, i.e., their x-y-z dimensions with x-y being the plane perpendicular to the interposer thickness or the z direction. For example, in certain cases, the size of the second interposer 104 is substantially smaller than the size of the first interposer 102 (see the 3D IC structure 11 in FIG. 4) such that the ability of the second interposer 104 in dissipating the heat from high-power die 100 is less compared to the first interposer 102 assuming they are made of the same material.

As shown in FIG. 4, the material of the first interposer 102 and the material of the second interposer 104 can be both diamond, which can have a TC of ≥2,000 W/m·K. Compared to the materials such as silicon (having a TC as about 148 W/m·K) and glass (e.g., SiO₂ having a TC of around 1 W/m·K), the heat dissipation benefits of diamond-included interposer is obvious. Besides diamond, in other embodiments, the high-TC interposer can be made of other HTC materials including cubic-boron nitride (c-BN), silicon carbide (SiC) or aluminum nitride (AlN), a composite material comprising a combination of these HTC materials or a composite material comprising one or more of these HTC materials and a lower TC (LTC) material such as silicon or glass.

In some embodiments, the high-power die 100 is cooled under a single-sided cooling topology. In those embodiments, the first interposer 102 is a HTC, LCTE interposer. In some embodiments, the first interposer 102 is a HTC interposer whose heat spreading ability is augmented by inclusion of a thermal enhancement portion (TEP) 116 under the first interposer 102 whose features will be described later. Though not shown, the TEP can be thermally coupled to the thermal vias and planes in the substrate structure 114 up to the peripherals of the substrate. In some embodiments, the second interposer 104 is a LTC interposer. A LTC interposer can be derived from glass, another LTC material such as a molding compound based fan-out structure with or without embedded dies, or a composite material including a LTC material and silicon.

In some embodiments, in order to enhance the heat dissipation capabilities, the high-power die 100 and/or the lower-power die 106 can be made of a material or a composite material with an effective TC higher than that of silicon (or silicon carbide).

In some embodiments, as shown in FIG. 3, the 3D IC structure 10 may include one or more bridge interconnect dies 107 (hereinafter “bridge die”) between the first interposer 102 and the second interposer 104. In some embodiments, the bridge dies 107 are leveled with the high-power die 100. In some embodiments, the bridge dies 107 include a plurality of interconnect structures (e.g. conductive lines, redistribution layers (RDL), through vias, etc.) configured to provide signaling and/or power delivery functions. The substrate of the interconnect structures in forming the bridge dies can include silicon, a HTC material, a LTC material, or a combination thereof.

The structures of bridge dies 107 can vary. For example, the bridge dies 107 may be formed by stacking interposer-lets made of silicon, glass, a HTCs material, a LTC material or a combination therefore the interposer-lets containing through vias and RDLs, similar to stacking of dies in forming the HBMs. They may also be formed by stacking fan-out layers with through vias and/or vertical metal wires, by stacking package-on-package (PoP) layers with through vias and/or vertical metal wires, or a combination of these configurations. In other examples, the bridge dies 107 can also be co-packaged with ICs using, for instance, fan-out processing.

Still referring to FIG. 3, the substrate structure 114 includes a thermal enhancement portion 116 located under the high-power die 100 and is thermally coupled to a HTC first interposer and the high-power die 100. In some examples, the TEP 116 can be positioned directly under the high-power die 100 (i.e., beneath the projected area of the high-power die 100). In other examples, the TEP 116 may partially overlap with the high-power die 100 in the vertical direction. In some embodiments, the TEP 116 can be located under the lower-power die 106 if the lower-power die 106 is also targeted for heat dissipation. The TEP 116 can be an opening exposing the underside of the first interposer to the liquid coolant during liquid immersion cooling, or filled with a HTC material such as diamond. In both cases, the TEP 116 is thermally coupled to the first interposer 102.

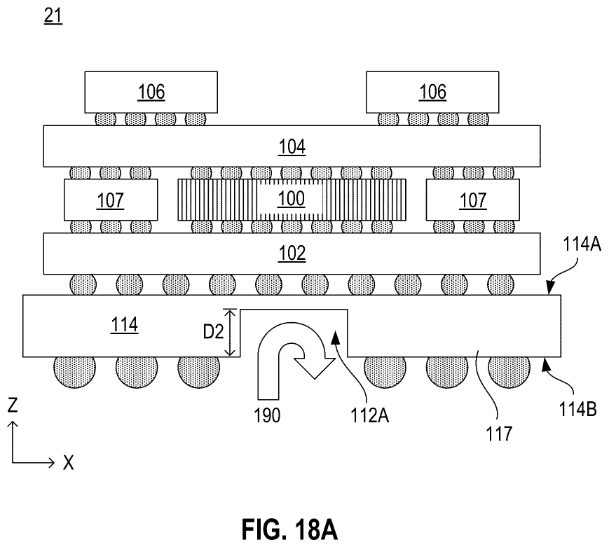

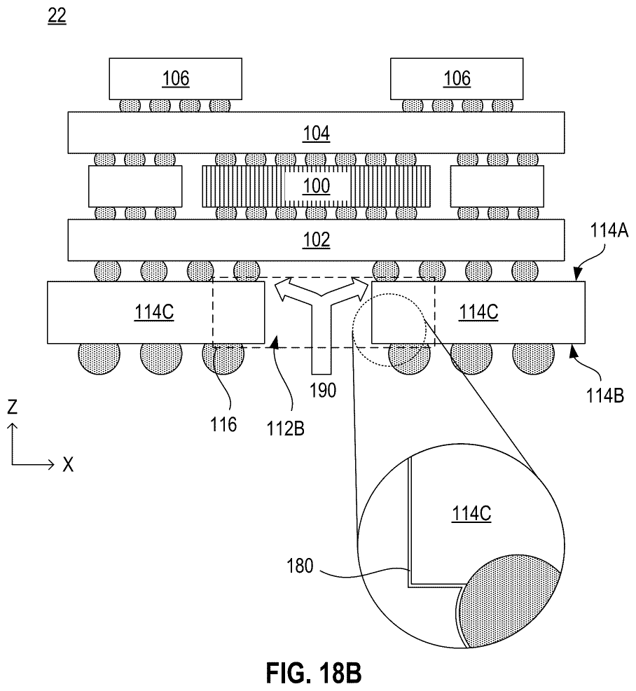

The 3D IC structure 10 can be cooled using a direct-to-chip liquid cooling method. For instance, a heat spreader with a cold plate bonded to it using a thermal interface material (TIM) can be in direct contact with the exposed upper surface of the 3D IC structure 10 again with the use of another TIM. The two TIMs here can be metallic or polymer based. Since the high-power die 100 is located beneath the second interposer 104, the cold plate/heat spreader sub-assembly (CHS) can be thermally coupled to the first interposer 102 which takes the heat away from the high-power die 100 to the first interposer 102 and then to the CHS through the use a HTC ring structure that constitutes an integral part of the CHS. Alternatively, liquid immersion cooling may be used in conjunction with the implementation of the TEP 116 in FIG. 4 and/or large interposers 102 and 104. In some embodiments, heat dissipation for the high-power die 100 (e.g., GPUs, CPUs, NPUs, TPUs, etc.) and/or the lower-power die 106 (e.g., HBMs) can be achieved by immersing the 3D IC structure 10 in a liquid coolant. Specifically, the liquid immersion cooling method can involve the use of a single-phase dielectric coolant, a two-phase dielectric coolant or water with a conformal surface passivation. The dielectric coolant may include a fluorocarbon or a hydrocarbon that is not electrically conductive. Due to the conductivity of water, a pre-coating operation may be required in some embodiments wherein the 3D IC structure 10 is coated with a conformal, pinhole-free insulation material such as parylene (see organic coating 180 in FIG. 18B).

In some embodiments, the 3D IC structure 10 can further include an optical device disposed on the first interposer 102 or the second interposer 104. The optical device is electrically and optically coupled with the high-power die 100 through the first interposer 102 or the second interposer 104. In some embodiments, the optical device can include a waveguide structure, a photonic IC, an electric IC and fiber optical interconnects I/Os.

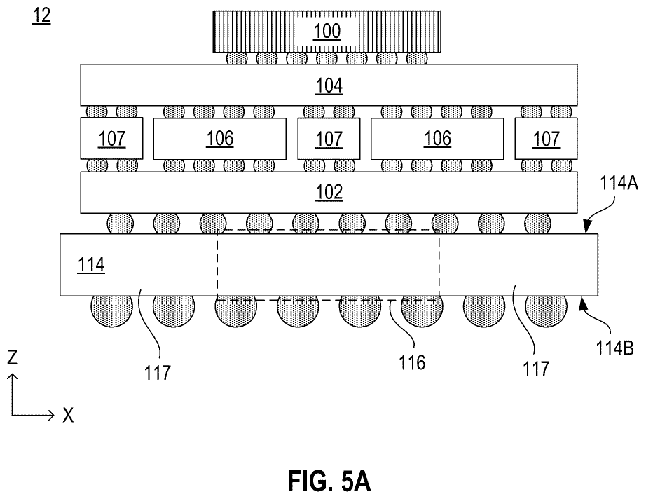

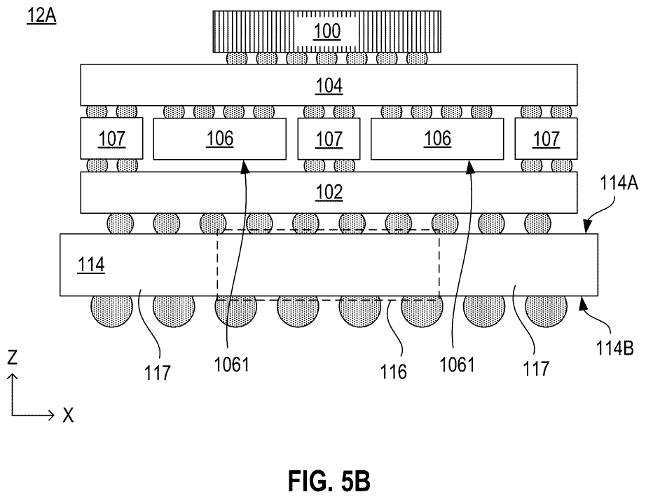

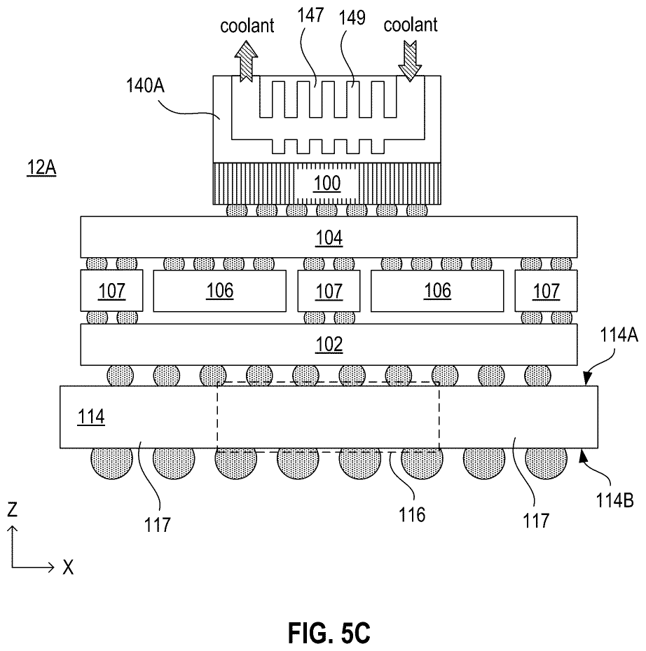

Referring to FIG. 5A, in some embodiments, the high-power die 100 can be disposed over the second interposer 104 instead of under the second interposer 104 in a 3D IC structure 12. In some embodiments, the lower-power dies 106 are disposed over the first interposer 102. In some embodiments, the lower-power dies 106 are sandwiched between the first interposer 102 and the second interposer 104. The first interposer 102 in the 3D IC structure 12 is a lower-TC interposer, whereas the second interposer 104 is a higher-TC, LCTE interposer. In contrast to the 3D IC structure 10 shown in FIG. 3, the high-power die 100 is located on the top of the 3D IC structure 12; and the lower-power dies 106 are situated under the second interposer 104 wherein the lower-power dies 106 can be electrically connected using, for instance, copper pillar micro-bumps and/or copper hybrid bonds to both the first interposer 102 and the second interposer 104.

In some alternative embodiments, referring to FIG. 5B, a 3D IC structure 12A can be formed by mounting the second interposer 104 over the first interposer 102 after the high-power die 100 and the lower-power dies 106 are mounted on opposite sides of the second interposer 104, and a side 1061 of the lower-power dies 106 is free from having conductive terminals, and therefore there is no micro-bump or a copper hybrid bond connecting the lower-power dies 106 directly to the first interposer 102.

Referring to FIG. 5C, this example illustrates the application of direct-to-chip liquid cooling to the high-power die 100 which is located on the top of the 3D IC structure 12 in FIG. 5A. In some embodiments, either a finned structure such as a silicon heat spreader with micro-fins (not shown) or a heat sink 140A with micro fins 147 and micro channels 149 is thermally coupled to the backside of the high-power die 100, allowing a liquid coolant to cool the high-power die 100 in close proximity using an high-speed flow impinging upon the finned structure or a liquid flow passing through the micro-channels with micro-fins.

In an alternative embodiment, the high-power die 100 can be a monolithic integrated circuit device that includes a plurality of micro-fins for impingement flow cooling on its backside. In this case, the second interposer 104 can be a HTC interposer for cooling the high-power die 100 from both sides. Alternatively, the second interposer 104 can be a LTC interposer depending on the power of the high-power die 100. In the latter case, the second interposer 104 can be made of a LTC material which is relatively thick to more effectively block the heat from the high-power die 100 from reaching the lower-power dies 106 beneath it.

Moreover, in DtC cases where the second interposer 104 is a LTC interposer, the dimensions of the second interposer 104 can be adjusted and co-optimized in conjunction with those of the HTC first interposer 102 such as no die overheating occurs. With liquid immersion cooling, the HTC interposer requires a larger area for heat exchange with the liquid coolant, while the low-TC interposer does not require such a large area.

In some cooling strategies, the second interposer 104 is a HTC interposer for heat dissipation, while the first interposer 102 can either be a HTC interposer or a lower-TC interposer (e.g., a silicon interposer), as most of the heat from the high-power die 100 is dissipated upward and sideways through the second interposer 104. When the costs of HTC interposers are high, the decision on whether to use HTC materials for both the first interposer 102 and the second interposer 104 should depend on the power of the high-power die 100, as well as on how best to strike a balance between cost, heat dissipation from the high-power die 100, the maximum operation temperatures of both the high-power die 100 and lower-power dies 106. In certain scenarios, the TC of the first interposer 102 can be equal to or lower than that of the second interposer 104.

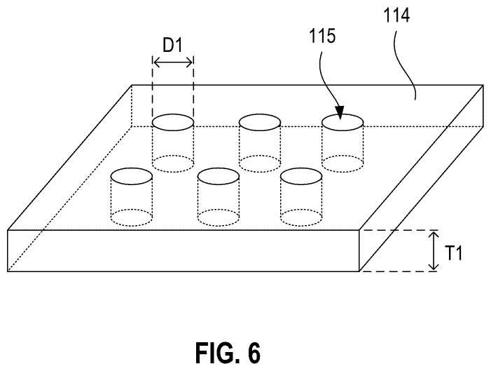

Referring to FIG. 6, in some embodiments, the substrate structure 114 may include a plurality of through channels 115 penetrating the substrate structure 114. These through channels 115 are designed to allow liquid coolant during liquid immersion cooling to pass through the substrate structure 114 and come into close contact with the heat sources (e.g., the high-power die 100 and the lower-power dies 106 either directly or through the first interposer 102) above the substrate structure 114. In some embodiments, the width D1 of the through channels 115 may be approximately 8 mm. In some cases, the width D1 on the two sides of the substrate structure 114 may differ due to manufacturing techniques. The thickness T1 of the substrate structure 114 may be around 1,700 μm in some embodiments. Additionally, like the through channels 115 penetrating the substrate structure 114, one or more open vias may be created in the interposers for providing channels that connect two sides of the interposers. For instance, these open vias can be created in the first interposer 102 and/or the second interposer 104 with a width ranging from about 20 μm to about 100 μm. In some embodiments, the through channels 115 in the substrate structure 114 and the open vias in the interposers can be created using a femtosecond laser or laser induced deep etching. For example, the femtosecond laser used to form the through channels 115 or the open vias may have a wavelength of approximately 1.03 μm, a pulse duration of less than about 500 fs, and a repetition rate of about 500 kHz. The process for creating a diamond-based interposer is similar to that of the silicon-based interposer, with one major difference lies in the hole creation process (i.e., the process of forming the open vias).

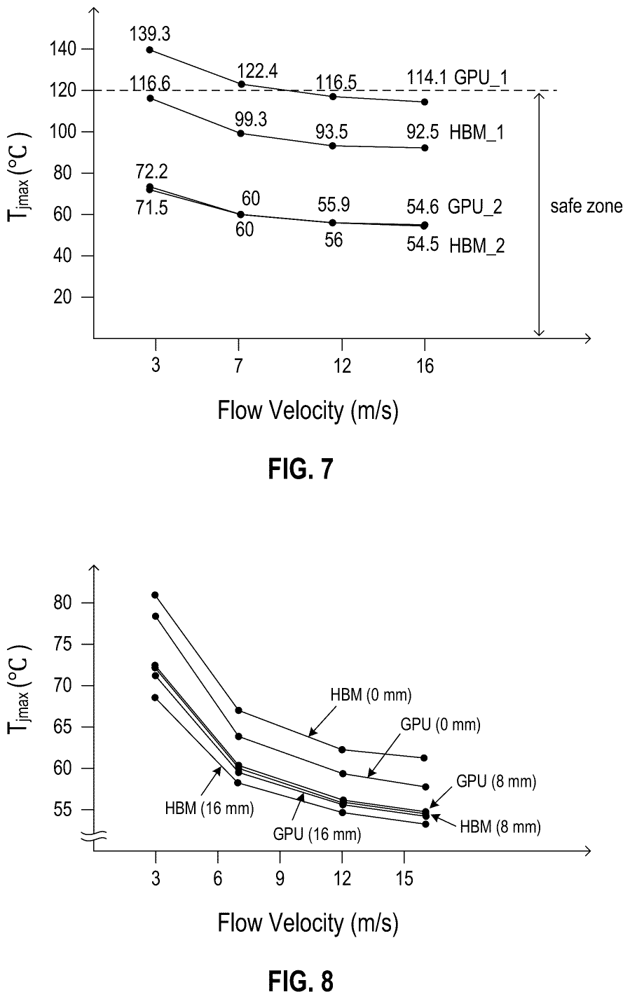

Referring to FIG. 7, which illustrates a simulation result of liquid immersion cooled 3D IC structures. In FIG. 7, GPU_1 and GPU_2 refer to the high-power die 100 in the 3D IC structure 10 and the 3D IC structure 12, respectively; while HBM_1 and HBM_2 refers to the lower-power dies 106 in the 3D IC structure 10 and the 3D IC structure 12, respectively. The simulation is performed under the input simulation conditions that: (a) using diamond interposer as the HTC interposer (the first and the second interposers, 102 and 104, in the 3D IC structure 10); (b) using glass (SiO₂) interposer as the LTC interposer (i.e., the second interposer 104 in the 3D IC structure 12); (c) using silicon interposer (i.e., the first interposer 102) under the lower-power dies in the 3D IC structure 12; (d) the power of GPU is 1,500 W; (e) 6 HBMs (HBM3, including 12 DRAM dies and 1 control IC per HBM) at 20 W/HBM; (f) using water as coolant; (g) ambient temperature of 20° C.; (h) the width of the through channels in the substrate structure is 8 mm; and (i) using the 2.5D IC package, die dimensions and interconnect structures similar to those in Nvidia® H100 GPU (2.5D IC structure). Put it simply, the primary difference between the 3D IC structure 10 and the 3D IC structure 12 for simulation is that the GPU in the 3D IC structure 10 is sandwiched by two diamond interposers, whereas the GPU in the 3D IC structure 12 is mounted on a SiO₂ interposer.

As shown in FIG. 7, the simulation result illustrates the maximum junction temperature (Tⱼₘₐₓ) as a function of flow rate under water immersion cooling. As shown in the simulation result, the 3D IC structure 12 can be over 50° C. cooler than the maximum operating temperature (120° C.), indicating that the GPU power can be increased possibly to over 2,000 W for higher performance. Furthermore, in the 3D IC structure 12, it can be expected that it is possible to replace the LTC interposer (e.g., SiO₂ interposer) with a HTC interposer (e.g., diamond interposer) for even better thermal performance. Regarding the 3D IC structure 10, there may still exist operable conditions using, for instance, larger diamond interposers and large channel widths for the temperatures of the GPU and HBMs to stay below the maximum operating temperature (120° C.).

Referring to FIG. 8, which illustrates the simulation result of the 3D IC structure 12 with different diameter of the through channels 115 traversing the substrate structure 114 (see FIG. 6). As shown in the figure, by increasing the width of the through channels 115 in the substrate structure 114 from 0 to about 8 mm, it can significantly reduce the temperatures of the GPU and HBMs. Beyond 8 mm, the effects are less pronounced.

In conventional 2D flip chip and 2.5D IC packaging, heat dissipation proceeds upward in the z direction through the backside of the processor to a heat spreader and to a heat sink or a cold plate, i.e., based on a one-sided cooling topology. In embodiments such as the 3D IC structure 10 and the 3D IC structure 12, heat dissipation or cooling can proceed one-sided (one-sided cooling topology) or dual-sided (dual-sided cooling topology), for example, when the high-power die 100 (e.g., GPU) is sandwiched between two HTC interposers in the 3D IC structure 10 or when the high-power die 100 is positioned between a HTC interposer and a liquid cooling mechanism involving a cold plate, cooling fins or an impinging coolant flow.

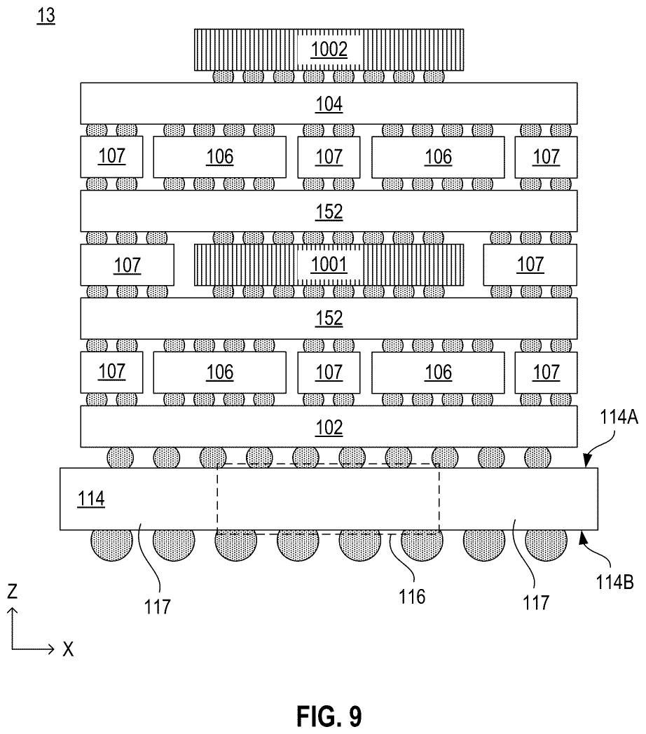

FIG. 9 illustrates another embodiment in which the 3D IC structure 13 is a combination of the 3D IC structures 10 and 12 described in the aforementioned embodiments. In this embodiment, two or more high-power dies, such as a first high-power die 1001 and a second high-power die 1002, can be included within the 3D IC structure 13 and positioned on different interposers. These high-power dies may exhibit heat dissipation features derived from the 3D IC structures 10 and 12. For instance, at least one of the high-power dies (e.g., the first high-power die 1001) may be sandwiched between two third HTC interposers 152 whose dimensions can be larger than indicated in FIG. 9 in a vertical direction, allowing it to be cooled efficiently through dual-sided cooling. The second high-power die 1002 which is located on the top side of the 3D IC structure 13 can be cooled liquid cooled using the approaches described for the cooling of the high-power die 100 in the embodiment of the 3D IC structure 12.

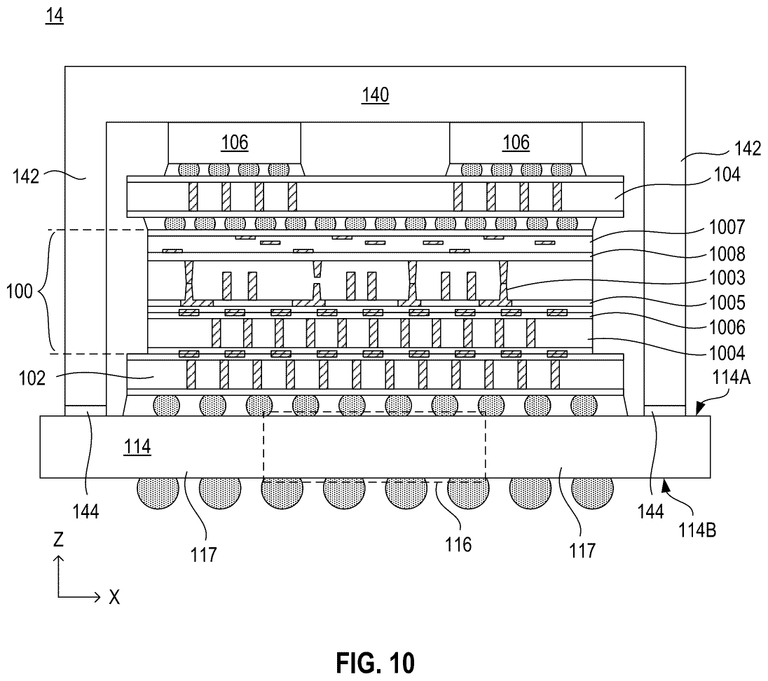

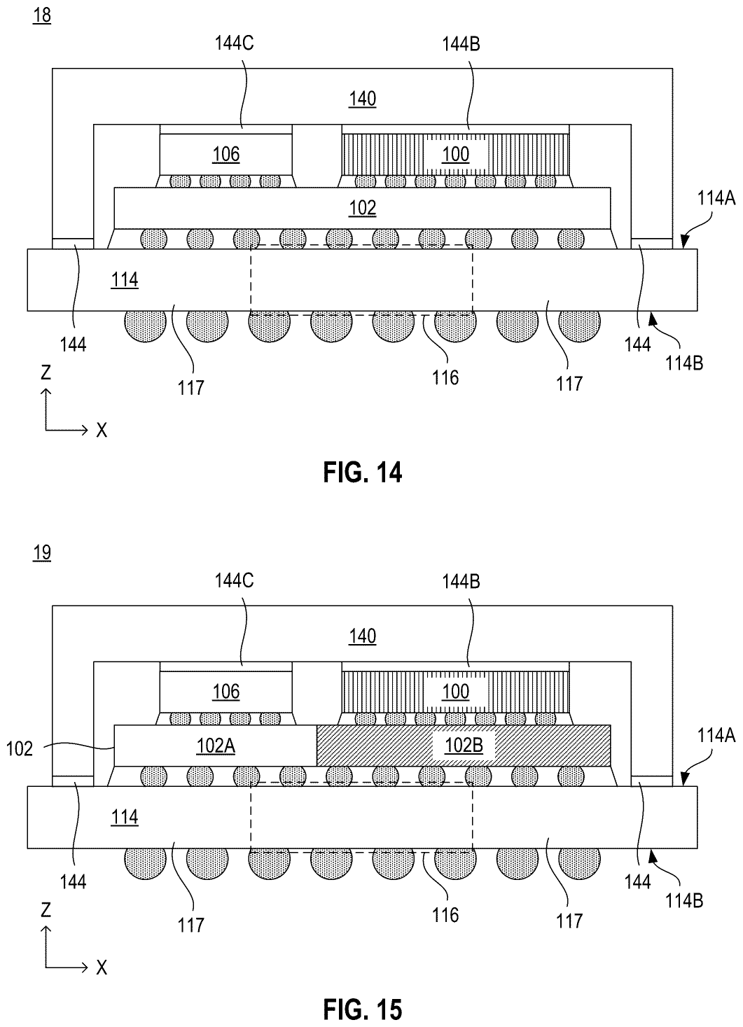

Referring to FIGS. 10 to 15, the present disclosure presents several structural approaches for demonstration purposes to enhance heat dissipation in 3D IC structures (see FIGS. 10 to 13), as well as in several enhanced 2.5D IC structures (see FIGS. 14 and 15). These thermally enhanced structures will enable more die-stacking design options, and higher-power processors and more processors to be integrated with more HBMs and other memory devices without die overheating to enhance performance for HPC, data centers, AI applications, and other high-end applications such as networking and automotive.

Referring to FIG. 10, in some embodiments, a HTC heat spreader 140 in a 3D IC structure 14 can be disposed on and thermally coupled to the first surface 114A of the substrate structure 114. The heat spreader 140 is also thermally coupled to the backside of the lower-power dies 106 at the top of the 3D IC structure 14. The heat spreader 140 can include a plurality of HTC supporting portions 142 with a height substantially equal to or similar to the stacking height of the dies in the 3D IC structure 14. In some embodiments, a spacer 144 is placed between the supporting portions 142 and the first surface 114A of the substrate structure 114. In the present disclosure, spacers can be HTC TIMs, and these HTC TIMs are used interchangeably since people skilled in the art can appreciate that HTC TIMs are exemplifying embodiments as one kind of the HTC spacers and using such term (i.e., HTC TIMs) does not exclude other suitable materials composing the HTC spacers at the specific position described. The spacer 144 can be a non-electrically-conductive paste or film. In some embodiments, the 3D IC structure 14 includes a first interposer 102 over the first surface 114A of the substrate structure 114. The first interposer 102 can be a HTC interposer; for example, it can be a diamond-based interposer with a plurality of through vias and RDLs on the two opposite sides of the first interposer 102 for electrical connection with adjacent electronic components. In the 3D IC structure 14, the high-power die 100 is disposed over the first interposer 102. In some embodiments, the high-power die 100 can have a backside power delivery network (BSPDN) structure 1003 electrically connected and thermally coupled to and a HTC carrier 1004 on the side facing the first interposer 102. Compared to the BSPDN design in some comparative embodiments, the BSPDN structure 1003 with the carrier 1004 in the present disclosure uses a diamond-based carrier/interposer with through vias and RDLs on both the top and bottom sides, whereas the BSPDN design in some comparative embodiments uses silicon as the carrier material on the top side of the high-power die 100. Because the diamond-based carrier has a thermal conductivity (≥2,000 W/m·K) significantly greater than that of a silicon-based carrier (about 150 W/m·K), the BSPDN design (i.e., the stack of the BSPDN structure 1003 and the carrier 1004) greatly enhances the thermal dissipation capabilities for the high-power die 100. In some embodiments, the high-power die 100 may further include a front-end-of-line (FEOL) structure 1008, a local interconnect layer and an intermediate interconnect layer 1007 (which may include redistribution layers on top of the intermediate interconnect layer) bonded to the second interposer 104, and a global interconnect layer 1005 bonded to a RDL 1006 of the carrier 1004. The local/intermediate interconnect layer 1007 and the global interconnect layer on both sides of the high-power die 100 can be electrically connected to adjacent electronic components using copper hybrid bonding or flip chip (not shown).

In other embodiments, a high-power die 100 based on a traditional front-side power delivery network (FSPDN) can also be used in place of the BSPDN-based high-power die 100 in the 3D IC structure 14. In this case, the FEOL side of the high-power die 100 is facing down (instead of facing up in FIG. 10) and is bonded to the first interposer 102. The high-power die 100 also contain through vias which traverse the thickness of the die connecting the BEOL layer between the FEOL layer and the first interposer 102 to the RDL on the opposite side (backside) of the high-power die 100.

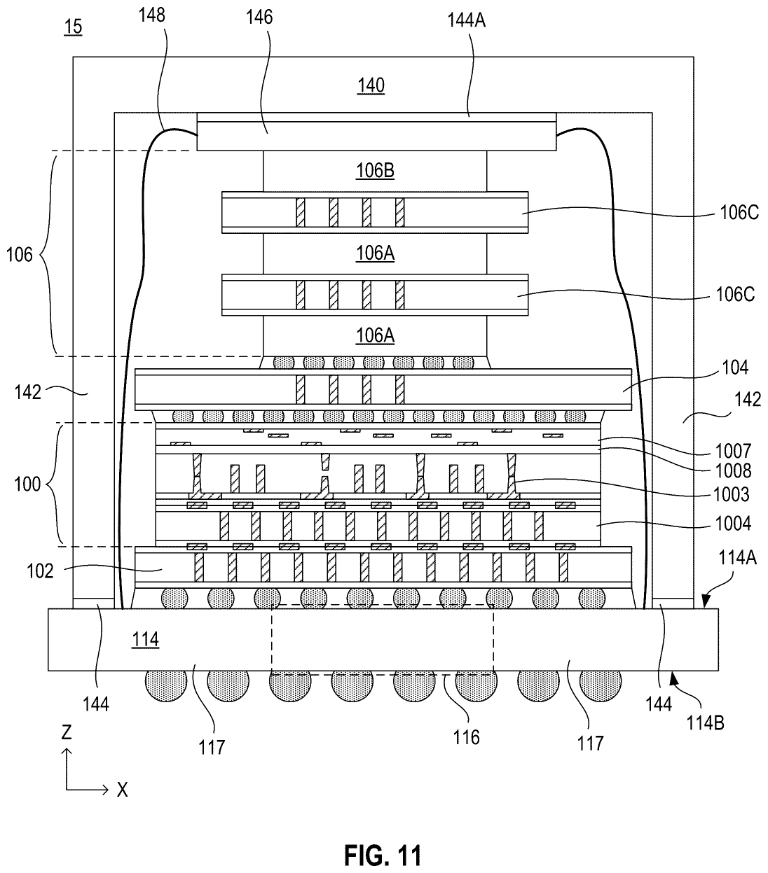

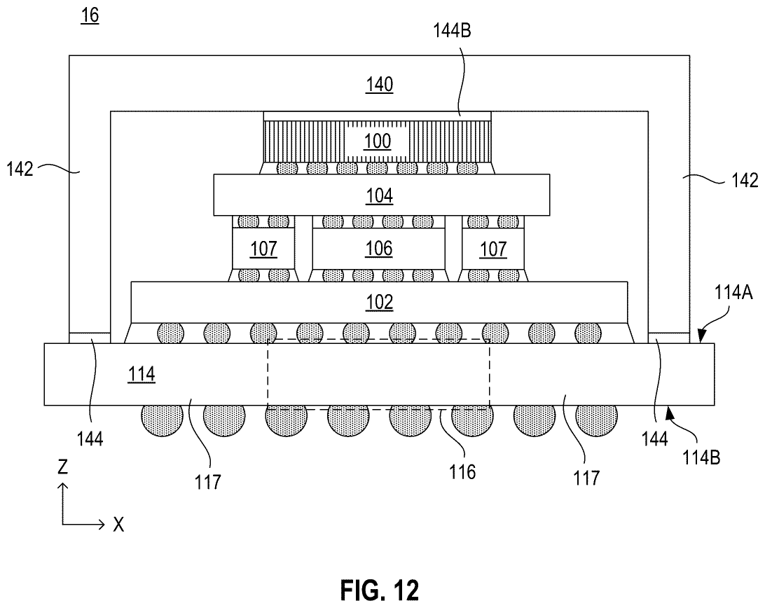

Referring to FIG. 11, in some embodiments, a HTC heat spreader 140 in a 3D IC structure 15 can be disposed on and thermally coupled to the first surface 114A of the substrate structure 114 and the backside (top side in FIG. 12) of the 3D die stack. The 3D IC structure 15 includes a dual-sided power supply, featuring a BSPDN-based high-power die 100 as shown in the embodiment in FIG. 10, and an upper substrate 146 above and is both electrically connected and thermally coupled to the lower-power die 106. The upper substrate 146 is electrically connected to power connecting wires 148 which, in turn, are electrically connected to the substrate structure 114 for power delivery and signaling. In some embodiments, the upper substrate 146 is a HTC, LCTE diamond-based interposer with a plurality of through vias and RDLs on both sides, or a HTC, LCTE clad metal (e.g., copper-invar-copper, CIC) interposer with a plurality of through vias and RDLs on both sides. Additionally, a spacer 144A can be a HTC TIM placed between the heat spreader 140 and the upper substrate 146 to aide in heat dissipation. As shown in FIG. 11, for example, the lower-power die 106 may optionally include a plurality of diamond-based interposers 106C with through vias between two adjacent dies 106A or between the die 106A and the die 106B. The lower-power die 106 in FIG. 11 can be a combination of DRAM dies (e.g., the die 106A) and a control IC (e.g., the die 106B). In some embodiments, the BSPDN-based high-power die 100 can also be replaced with a FSPDN-based one. Although high-power die and lower-power die are cited herein, they can be used in the 3D IC structure 15 interchangeable. This also applies to all other 3D IC structures disclosed herein.

Referring to FIG. 12, in some embodiments, a HTC heat spreader 140 in a 3D IC structure 16 can be disposed on and thermally coupled to the first surface 114A of the substrate structure 114 and the backside (top side) of the high-power die 100. The heat spreader 140 draws the heat from the high-power die 100 with the help of a spacer 144B. The spacer 144B can be a HTC TIM. Another spacer 144 can be a HTC TIM positioned at the interface between the substrate structure 114 and the supporting portions 142 of the heat spreader 140. The 3D IC structure 16 can be cooled using liquid immersion through openings (not shown) in the heat spreader, open vias in the first interposer 102 and TEP 116 in the substrate structure 114. In some embodiments, interconnect structures based on, for instance, micro-bumps, solder bumps and/or solder balls, etc. can be encapsulated with a HTC encapsulant. In some embodiments, the second interposer 104 is a LTC interposer to block the transfer of thermal energy from the high-power die 100 to the lower-power die 106 underneath. The second interposer 104 may also have a plurality of air cavities under certain hot spots of the high-power die 100, which help minimize thermal impacts on and insulate the lower-power dies 106 during direct-to-chip cooling (as air has a thermal conductivity of only about 0.03 W/m·K) or which allows liquid coolant to access the underside of the high-power die 100 during liquid immersion cooling. The first interposer 102 can be a silicon interposer, a LTC interposer or a HTC interposer with through vias and RDLs. Optionally, the lower-power die 106 can be bonded to the first interposer 102 (or a laminate substrate if the first interposer 102 is a laminate substrate) and the second interposer 104, or only to the second interposer 104. In some embodiments, the lower-power die 106 can also be pre-assembled in a molded fan-out layer prior to bonding to the first interposer 102. In some embodiments, aside from the heat spreader 140, the 3D IC structure 16 can optionally be molded and coated with a conformal coating such as parylene, to prevent short circuits or corrosion during liquid immersion.

In some lower-end applications, implementing a LTC interposer or a silicon interposer under the lower-power die 106 may not be required. However, when both the heat dissipation of the lower-power die 106 and the thermal impact from the high-power die 100 are considered in totality, high-TC interposers, such as diamond-based interposers, can be inserted between the DRAM dies in the lower-power die 106 to aid in heat dissipation, while a LTC interposer over the lower-power die 106 can minimize thermal impact.

In some embodiments, the heat spreader 140, particularly the portion over the high-power die 100, can be replaced with a vapor chamber.

In some embodiments, the heat spreader 140 in the 3D IC structure 16 can include a plurality of liquid channels. This heat spreader, with liquid channels and fins inside, can remove heat generated by the high-power die 100 through the flow of the liquid coolant. Additionally, since the coolant does not come in direct contact with the dies of the 3D IC structure 16, encapsulating the 3D IC structure is unnecessary with a conformal layer.

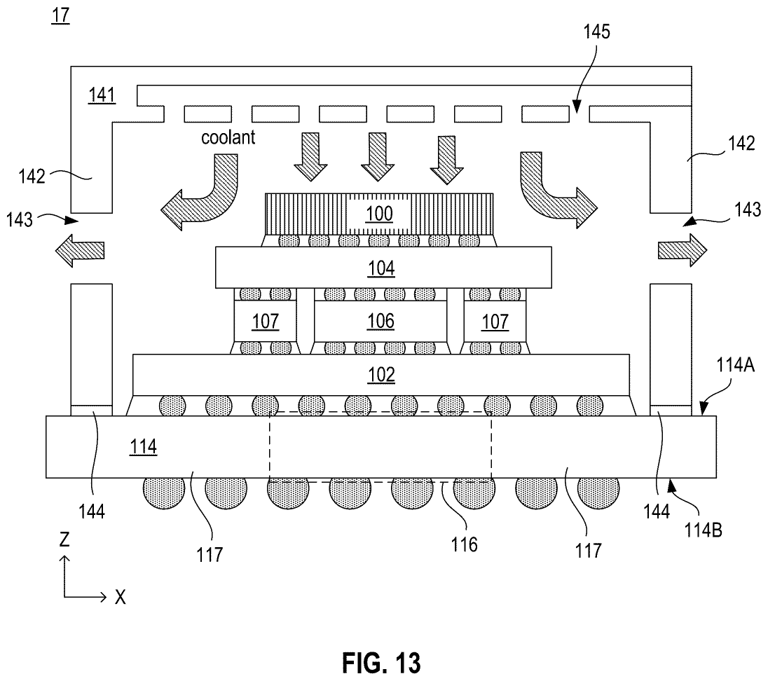

Referring to FIG. 13, in some embodiments, the 3D IC structure 17 is cooled using liquid immersion cooling. As shown in FIG. 13, a liquid coolant, which can be water or a dielectric coolant, may enter a built-in channel of an impinging-flow coolant distribution unit 141 over the high-power die 100 and impinge upon the high-power die 100 as well as the underlying second interposer 104, the lower-power die 106, the bridge dies 107, the first interposer 102, and the substrate structure 114. The liquid coolant is confined and guided by the orifices or openings in the supporting portions 142 disposed on the substrate structure 114 which supports the distribution unit 141 with the liquid coolant subsequently exiting though the openings 143 in the supporting portions 142 to complete the heat exchange process. In some alternative embodiments, after entering the built-in channel of the distribution unit 141, the liquid coolant can impinge at specific flow rates upon the high-power die 100 through one or more micro-nozzles 145 to enhance the cooling efficiency.

Overall, as shown in FIGS. 10 to 13, and further referring to FIG. 5C, the 3D IC structures are compatible with a wide range of cooling techniques, at least including air cooling, direct-to-chip liquid cooling, and liquid immersion cooling. Moreover, the efficiency of liquid cooling can be enhanced by using coolant jets/micro-jets directed at the high-power die (i.e., the processor) located at the top of the 3D IC structures, and/or by attaching a vapor chamber to the backside of the high-power die 100 using a HTC TIM with the vapor chamber cooled by the coolant jets.

Additionally, referring to FIGS. 14 and 15, the aforementioned cooling techniques for the 3D IC structures can also be applied to 2.5D IC structures for enhanced thermal performance. For instance, as shown in FIG. 14, both the high-power die 100 and the lower-power die 106 are disposed on the first interposer 102, and both the high-power die 100 and the lower-power die 106 are in contact with and thermally coupled to the inner side of the heat spreader 140 for heat dissipation. In some embodiments, the spacer 144B and a spacer 144C can be a HTC TIM placed between the heat spreader 140 and the top sides of the high-power die 100 and the lower-power die 106, respectively. Another spacer 144 which can also be a HTC TIM can be inserted between the heat spreader 140 and the substrate structure 114. In another embodiment, as shown in FIG. 15, the interposer (i.e., the first interposer 102) supporting the high-power die 100 and the lower-power die 106 is a composite interposer, which can have different thermal conductivities in different areas due to the different combinations of materials in forming the interposer substrate. For example, the first interposer 102 can include a first portion 102A made of a LTC, LCTE material and a second portion 102B made of a HTC, LCTE material. The high-power die 100 is placed over the second portion 102B containing the HTC material for enhanced heat dissipation, while the lower-power die 106 is positioned over the first portion 102A contain the LTC material to block the heat from the high-power die 100.

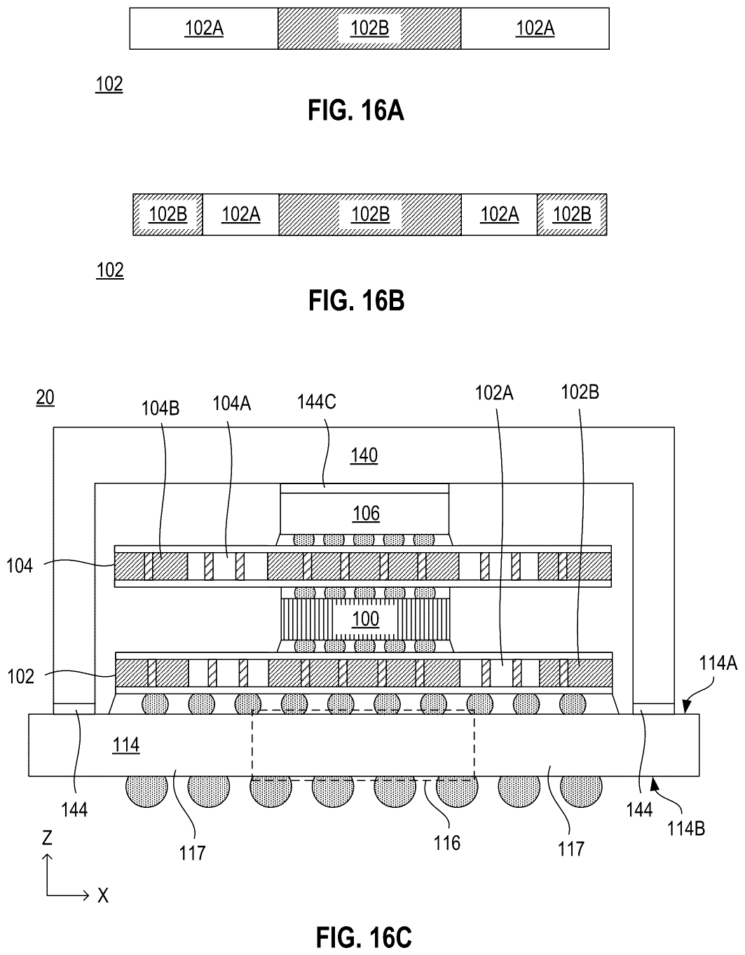

FIGS. 16A and 16B illustrate some examples of composite interposers. As shown in the figures, a single composite interposer can have more than one first portion (e.g., labeled as 102A) and/or more than one second portion (e.g., labeled as 102B). The distribution of materials with desired thermal conductivities depends on the placement of the dies. In some embodiments, more than two materials with different thermal conductivities can be included in a single composite interposer. FIG. 16C illustrates an example where both the first interposer 102 and the second interposer 104 are composite interposers. In a 3D IC structure 20, both the high-power die 100 and the lower-power die 106 are disposed on the second portions (labeled as 102B and 104B) that may include a HTC material, while the first portions (labeled as 102A and 104A) of these composite interposers are exposed.

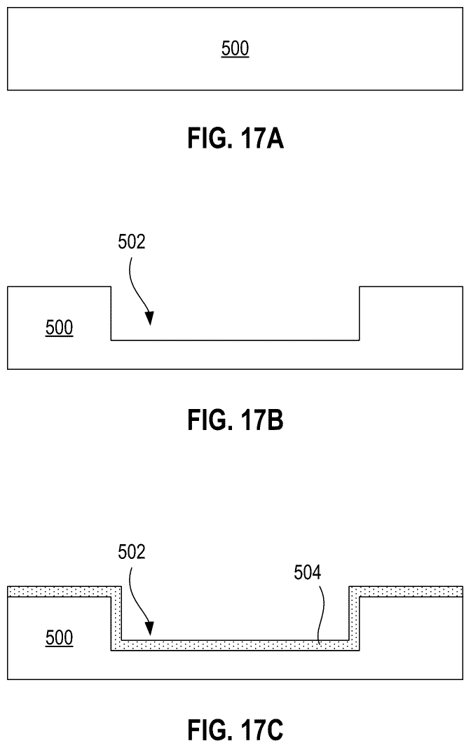

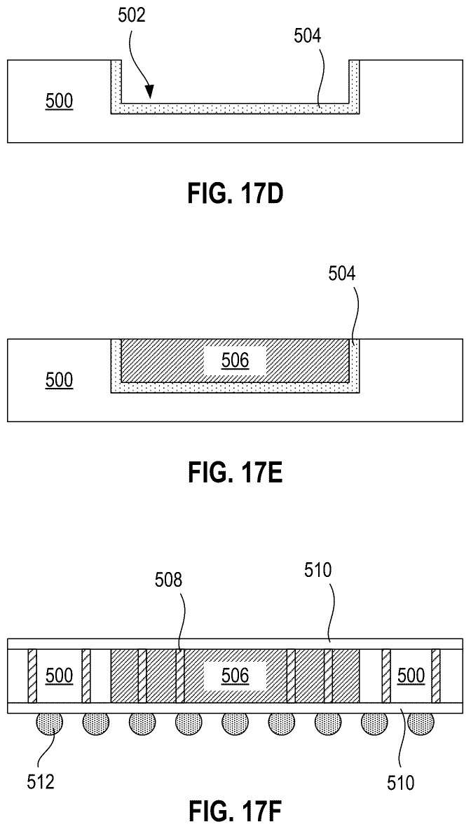

FIGS. 17A to 17F illustrate a method for forming the composite interposer according to some embodiments of the present disclosure. As shown in FIG. 17A, a substrate 500 is provided. The substrate 500 can be a silicon substrate or another suitable substrate, depending on the requirements of the composite interposer. As shown in FIG. 17B, a cavity 502 is formed on the upper side of the substrate 500. Next, as shown in FIG. 17C, a seed layer 504 is formed over the upper side of the substrate 500, covering the surface of the cavity 502. The material of the seed layer 504 may include Ir. Also, multilayer substrates have been developed with iridium buffer layers deposited on metal oxide layers on silicon substrates (SrTiO₃/Si and YSZ/Si), oxide substrates like MgO and more recently sapphire, and KTaO₃. Then, referring to FIG. 17D, the seed layer 504 on the original surface of the substrate 500 is removed through a patterning operation. As shown in FIG. 17E, a material 506 different from that of the substrate 500 is deposited over the substrate 500. For instance, a CVD diamond deposition operation is performed to fill the cavity 502 with diamond, followed by a planarization operation. Referring to FIG. 17F, the substrate 500 can be thinned from the lower side thereby exposing the underside of the diamond. Following this, other interposer processing steps can ensue such as forming through vias 508 in the substrate 500, forming RDLs 510 on both sides of the substrate 500, and forming bonding structures 512 such as solder bumps or micro bumps.

In some embodiments, the substrate structure 114 in FIG. 16C can include a thermal enhancement portion 116 (TEP 116) in the region under the high-power die 100 as shown previously in FIG. 3. Referring to FIG. 18A, in some embodiments, the TEP 116 in the 3D IC structure 21 includes a recess 112A, retracted from the second surface 114B of the substrate structure 114. In some embodiments, a depth D2 of the recess 112A is at least 50% of a thickness of the other portion 117 of the substrate structure 114. The recess 112A which preferably contains thermal vias and planes above it can be utilized as a bottom channel for a fluid coolant 190 to pass through to enhance cooling efficiency. In other embodiments, the recess 112A can be used for embedding a HTC heat spreading component.

Referring to FIG. 18B, in some embodiments, a TEP 116 in a 3D IC structure 22 includes an opening (or a trench or a combination thereof) 112B allowing a fluid coolant 190 to rise above the first surface 114A of the substrate structure 114 through the opening 112B. In such embodiments, the opening 112B at the substrate structure 114 can be utilized to allow a liquid coolant (a dielectric coolant or a water-based coolant) to directly access the underside of the first interposer 102 supporting the high-power die 100 during liquid immersion cooling. To avid electrical shorts, a conformal layer such as CVD parylene needs to pre-deposited on all exposed surfaces in the liquid immersion bath. As shown ins FIG. 18B, the 3D IC structure 22 includes an organic coating 180 (see the enlarged portion) which can be parylene or another suitable material which covers a plurality of exposed surfaces of the substrate structure 114, the lower-power die 106, the high-power die 100, the first interposer 102, the second interposer 104, and side walls of the substrate structure 114 defining the opening 112B.

In the embodiments shown in FIGS. 18A and 18B, the recess and the opening of the TEP 116 in the substrate 114 can lead to a geometry that differs from other portions (117 in FIG. 18A and 114C in FIG. 18B) of the substrate structure 114. In other embodiments, the thermal conductivity of TEP 116 may differ from that of the other portions 117 of the substrate structure (see FIG. 18A).

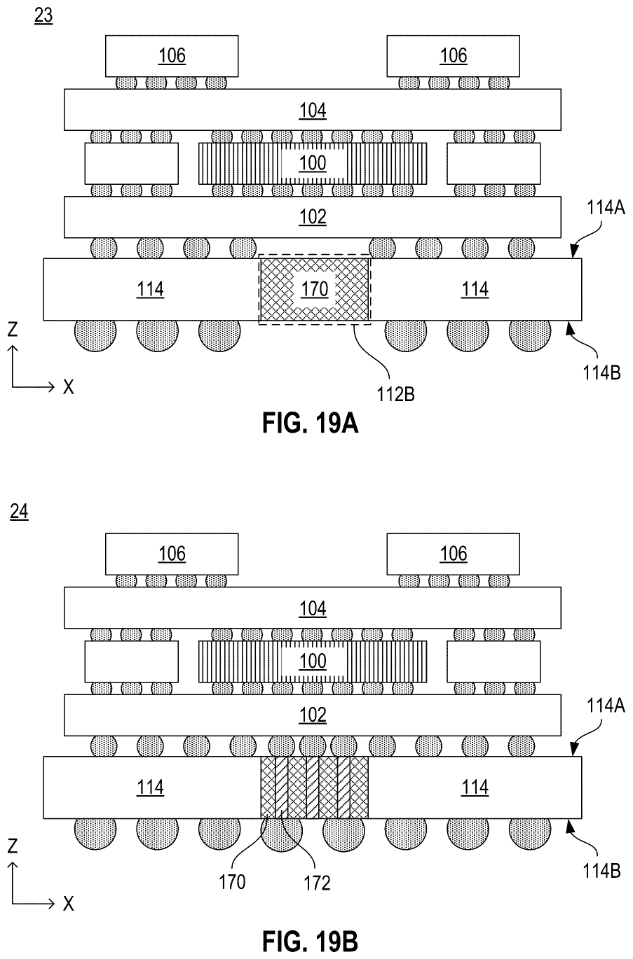

Referring to FIG. 19A, in some embodiments, a TEP in a 3D IC structure 23 includes the opening 112B, similar to the embodiment shown in FIG. 18B. However, in the embodiment shown in FIG. 19A, the opening 112B is filled with a HTC material 170. In some embodiments, the top and bottom surfaces of the HTC material 170 are coplanar with the first and second surfaces of the substrate structure 114, respectively. That is, the substrate structure 114 in FIG. 19A can essentially be a composite substrate, where the HTC material 170 is laterally surrounded by the material of the substrate structure 114, such as a LTC material like silicon, glass or BT/ABF materials in the case of an organic laminate substrate.

Referring to FIG. 19B, in some embodiments, a TEP in a 3D IC structure 24 not only includes a HTC material 170 but also has a plurality of through vias 172 penetrating the HTC material 170. One difference between the embodiments shown in FIGS. 19A and 19B is the capability of forming the electrical connection structure in the TEP of these 3D IC structures.

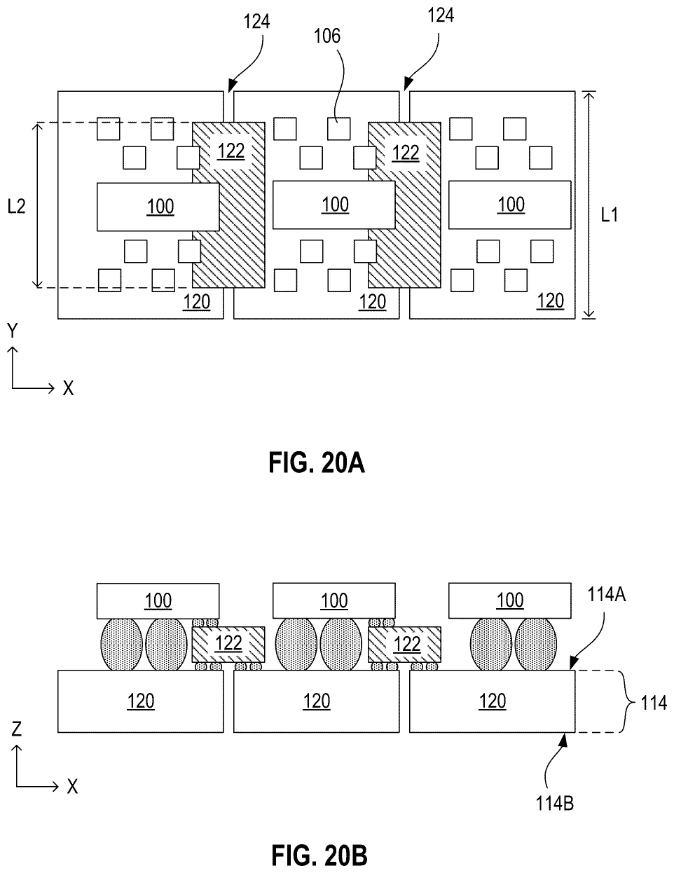

Moreover, in some embodiments, the substrate structure 114 may include not only a substrate with several geometric features, such as recesses and openings, but may also be a tiled substrate composed of multiple pieces connected through interconnect bridge structures. For example, as shown in the top view in FIG. 20A and the corresponding side view of the packaged structure in FIG. 20B, the substrate structure 114 can have a plurality of substrate units 120 physically separated from each other. The interconnect bridge structure 122 is configured to electrically or optically connect adjacent substrate units 120. In some embodiments, the length L1 of the substrate unit 120 is greater than the length L2 of the bridge structure 122, creating a plurality of tiny or very narrow (less than 1 mm wide) channels 124 between the adjacent substrate units 120 that may not be entirely covered by the bridge structure 122. Therefore, the channels 124 allow a liquid coolant to rise above the first surface 114A of the substrate structure 114 through the channels 124. By using a tiled substrate as the substrate structure 114, the channels 124 can function as fluid channels to enhance liquid immersion cooling efficiency.

In some embodiments, the bridge structure 122 is a silicon interconnect bridge electrically (and/or optically) connecting two adjacent substrate units 120. In some embodiments, the bridge structure 122 may include a plurality of TSVs and RDLs on both sides. In other embodiments, the bridge structure 122 can be mounted on the lower sides of the adjacent substrate units 120, not just on the top side as shown in FIG. 20B. The bridge structure 122 can also be partially located under the high-power die 100 and/or the lower-power die 106.

In some embodiments, the tiled substrates can be interconnected by a silicon bridge using a process consisting of depositing a non-conductive paste (NCP) on the silicon bridge 122 bonding the bridge using, for example, thermo-compression bonding (TCB) to one of the substrate units 120, curing the NCP and then the above steps are repeated to bond the bridge to the second substrate unit 120.

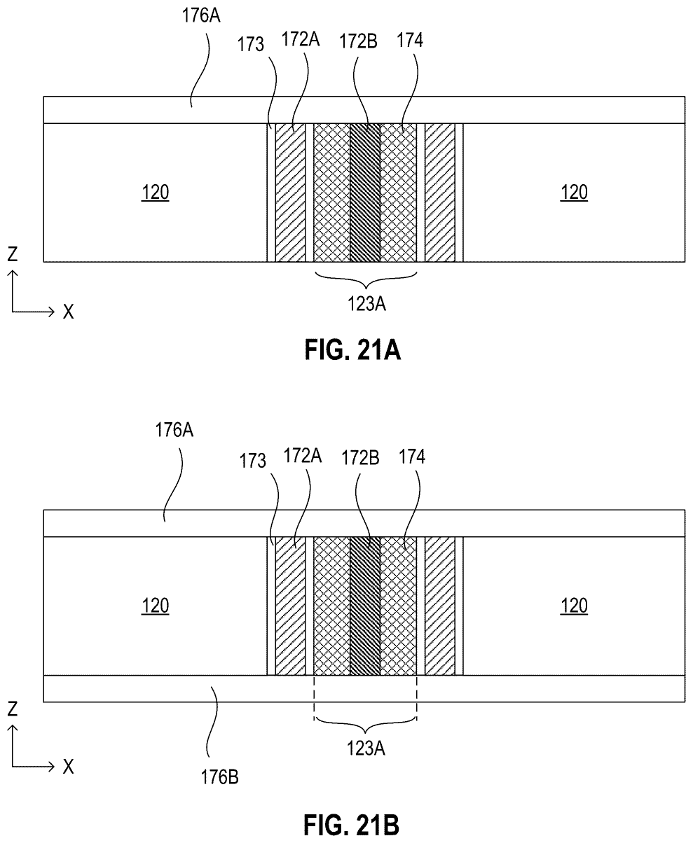

FIGS. 21A and 21B illustrate two tiled substrate examples involving an interconnect bridge interposer 123A between two adjacent substrate units 120. The bridge interposer 123A is substantially leveled with the two adjacent substrate units 120. In some embodiments, the bridge interposer 123A includes one or more of TSV 172B traversing the thickness of the bridge substrate 174 which can a silicon substrate. In some embodiments, there exist two TMVs 172A laterally surrounded by a molding compound 173 alongside but electrically isolated from the bridge interposer 123A. In some embodiments, one side of the bridge interposer 123A may include a RDL 176A. In other embodiments, as shown in FIG. 21B, two opposite sides of the bridge interposer 123A may contain RDL 176A and RDL 176B. The TSV 172B traverses a thickness of the bridge interposer 123A and connecting RDL 176A and RDL 176B.

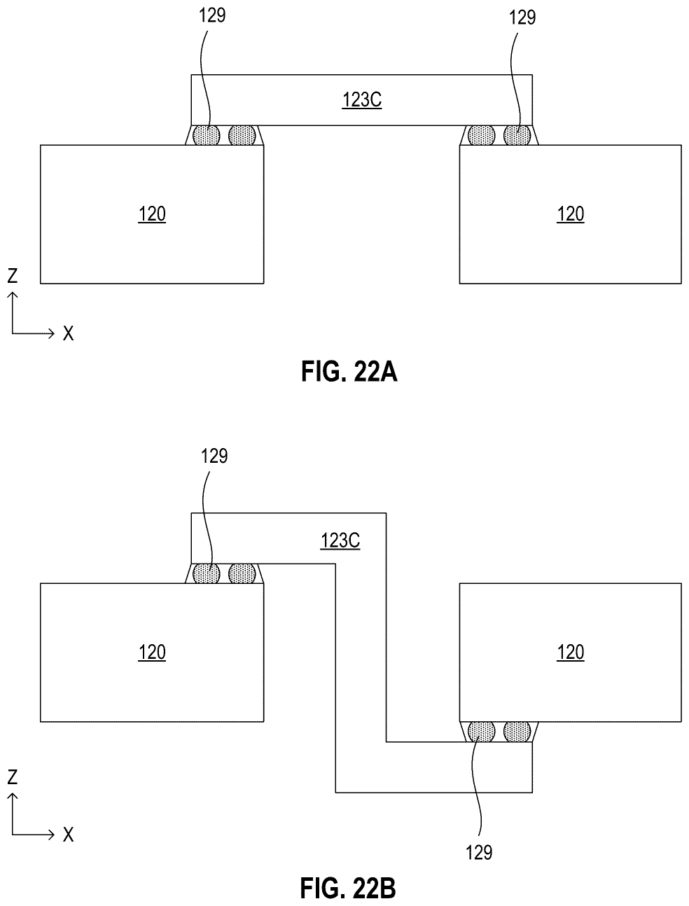

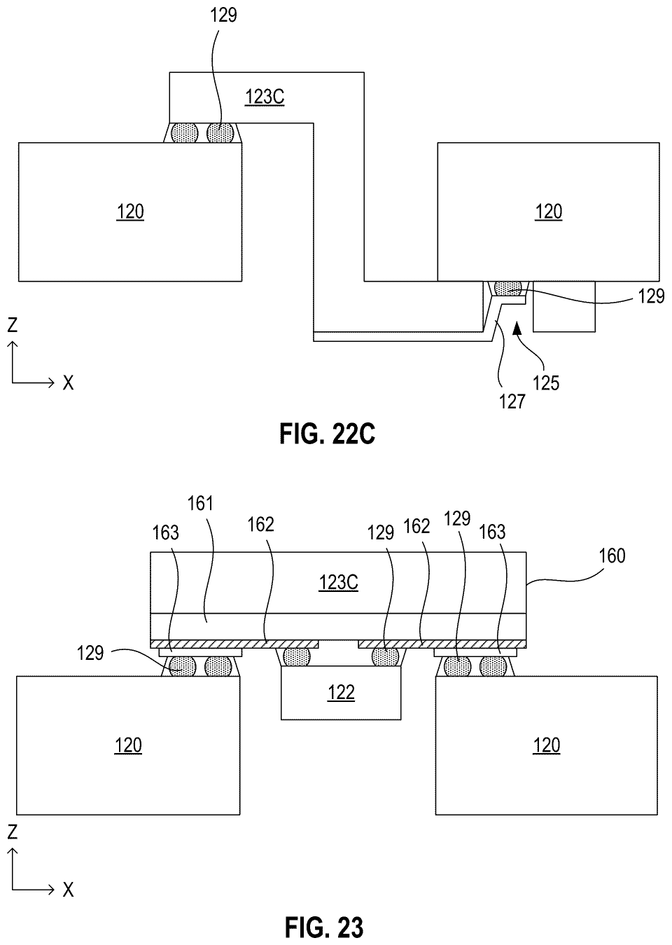

Referring to FIGS. 22A to 22C, which illustrate some examples of using flexible printed circuit (FPC) 123C as an interconnect bridge structure. FPC 123C can include a film made of polyimide or other types of flexible materials. As shown in FIG. 22A, FPC 123C can be mounted on the same side of adjacent substrate units 120, whereas as shown in FIG. 22B, FPC 123C can also be mounted on the opposite sides of adjacent substrate units 120, and therefore FPC 123C is connected to the same side or opposite sides of adjacent substrate units, in different embodiments. Moreover, as shown in FIG. 22C, FPC 123C may embody a window opening 125 and a bent lead 127 formed by a lead forming operation following the forming of the window opening 125. The bent lead 127 can extend into the window opening 125 and be in contact with the bonding structure such as surface finish, a gold bump or a micro-bump 129 exposed in the window opening 125. In some embodiments, FPC 123C is electrically connected to adjacent substrate units 120 or an integrated circuit through, for example, micro-bumps 129. Generally, each of the micro-bumps 129 is encapsulated.

Referring to FIG. 23, in some embodiments, a hybrid bridge structure 160 (HBS) can be used for bridging adjacent substrate units 120. HBS 160 can be formed using a combination of silicon bridge FPC. In some embodiments, the bridge structure 122 of FIG. 23 is mounted on a side of a FPC 123C through a plurality of micro-bumps 129 or gold bumps, where FPC 123C further includes a base film 161 (e.g., polyimide) to facilitate finer routing. A plurality of metal pads 162 (e.g., copper pads) are positioned on the surface of the base film 161 to electrically connect the substrate units 120 to the hybrid bridge structure 160 through the micro-bumps 129. In some embodiments, the solder mask 163 is disposed between the micro-bumps 129 and the metal pads 162 on the connection path between the base film 161 and the substrate units 120. The solder mask 163 can possess desired patterns to define the locations of electrical connection between the solder bumps 129 and the metal pad 162. In some embodiments, the bridge structure may also contain active functions.

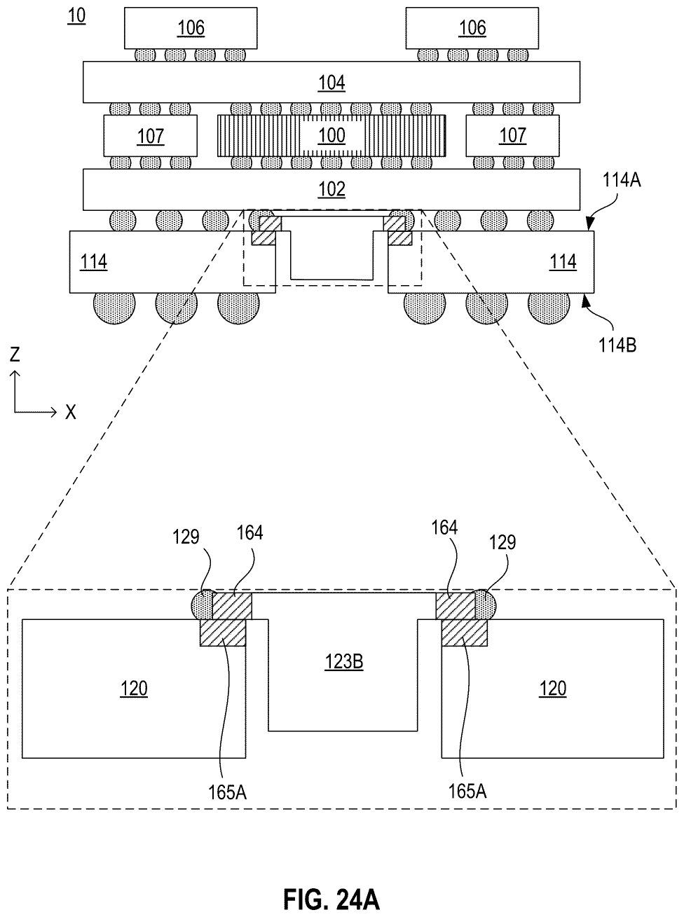

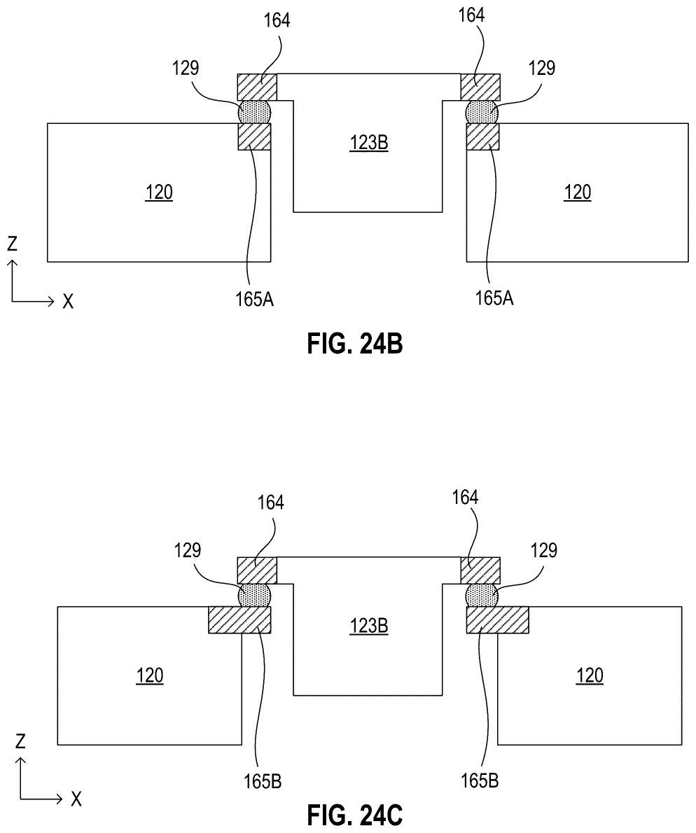

Referring to FIGS. 24A to 24C, in some embodiments, an edge interconnect bridge structure 123B can be used to connect the substrate units 120. The edge interconnect bridge structure 123B includes extended metal leads or extended metal/passivation leads for enhanced structural integrity, both containing appropriate surface finishes for subsequent bonding. In these embodiments, the edge interconnect bridge structure 123B can be a form of silicon bridge structure that connects the adjacent substrate units 120 through the first surface 114A of the substrate structure 114 (regarding the first surface 114A, see FIG. 3). As shown in FIGS. 24A to 24C, each of the edge interconnect bridge structures 123B includes a T-shape profile from a cross-sectional perspective, and the edge interconnect bridge structure 123B further includes two edge pads 164 made of conductive materials located at opposite sides of the edge connection bridge structure 123B. The edge pads 164 of the edge interconnect structure are electrically connected to the edge pads 165A or the extended edge pads 165B of adjacent substrate units 120. The micro-bumps 129 can be used to bond the edge pads 164 and the edge pads 165A (or the extended edge pads 165B) of the edge connection bridge structures 123B and the substrate unit 120, respectively. In some embodiments, the micro-bumps 129 are encapsulated (not shown in FIGS. 24A to 24C).

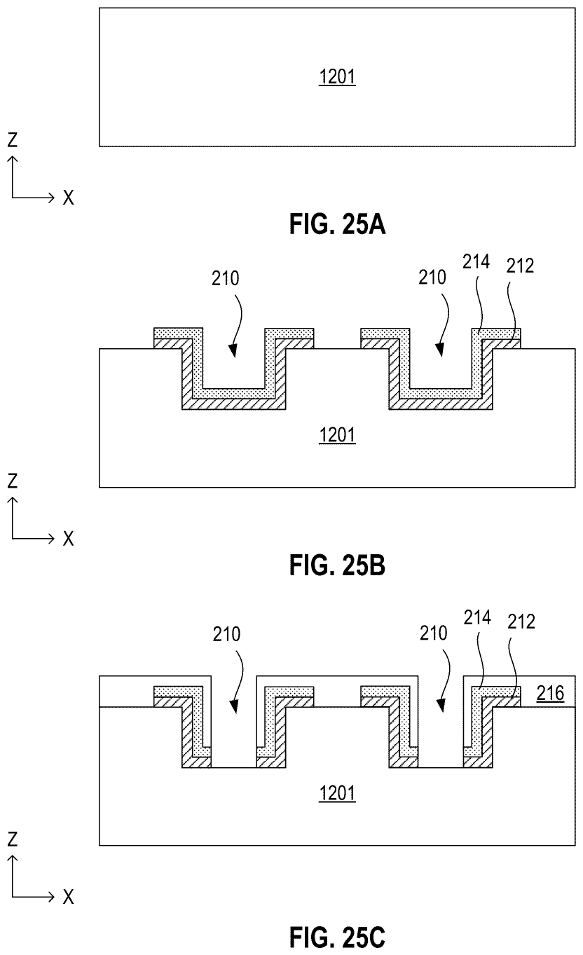

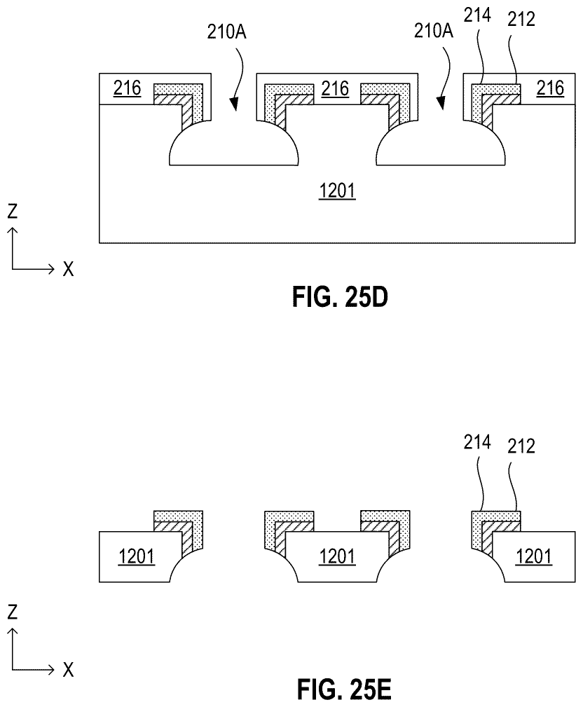

FIGS. 25A to 25E illustrate a method for forming the edge interconnect bridge structures according to some embodiments of the present disclosure. As shown in the figures, a substrate 1201 without edge pads is patterned from a side thereof to form one or more cavities 210. Then, a metal layer 212 and a passivation layer 214 can be formed subsequently in the cavities 210 by deposition operations. The stack of the metal layer 212 and the passivation layer 214 is patterned to expose a portion of an upper surface of the substrate 1201. Referring to FIG. 25C, following the deposition and patterning of a photomask 216 and the removal of a portion of the metal layer 212 and the passivation layer 214 to expose a bottom surface of the cavities 210, these cavities 210 are further patterned to form cavities 210A in FIG. 25D. As shown in FIGS. 25D and 25E, the photomask 216 is removed and the substrate 1201 is thinned and planarized from a backside. After dicing, each of the substrate 1201 with metal layer 212 at the corners thereof, can be used as an edge interconnect bridge structure. In some other embodiments, the formation of the passivation layer 214 can be omitted.

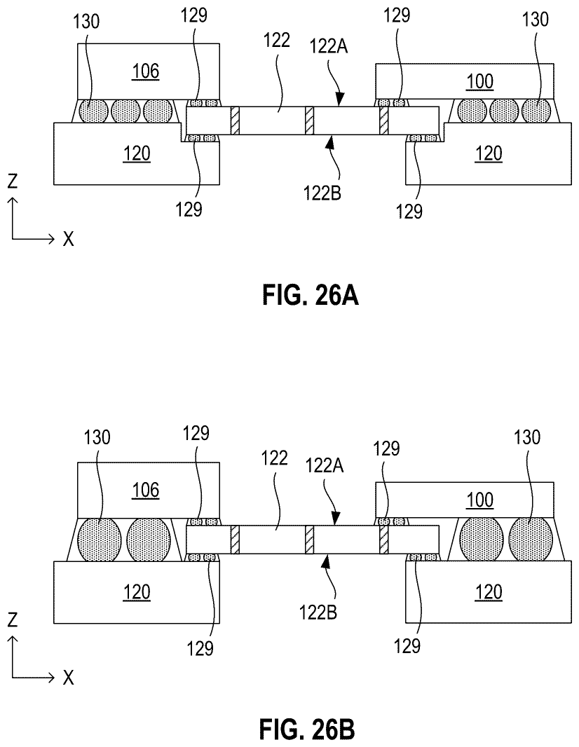

Referring to FIGS. 26A and 26B, in some embodiments, a dual-sided interconnect bridge structure 122 is connected to adjacent substrate units 120, high-power dies 100 and/or lower-power dies 106. As shown in FIG. 26A, one side of the bridge structure 122 is connected to both a substrate unit 120 and the lower-power die 106, wherein a first side 122A of the bridge structure 122 is electrically connected to the lower-power die 106 through the micro-bumps 129, and a second side 122B of the bridge structure 122 is electrically connected to the substrate unit 120 through the micro-bumps 129. The lower-power die 106 is further electrically connected to the substrate unit 120 through solder bumps or micro-bumps 130. On the other side of the bridge structure 122, the first side 122A of the bridge structure 122 is electrically connected to the high-power die 100 through micro-bumps 129, and the second side 122B of the bridge structure 122 is electrically connected to the other substrate unit 120 through micro-bumps 129. The high-power die 100 is further electrically connected to the other substrate unit 120 through solder bumps or micro-bumps 130. Between the embodiments shown in FIGS. 26A and 26B, some of the substrate units 120 can have recesses (see FIG. 26A) created by standard substrate processes.

The substrate structure in these embodiments can be ultra-large, ultra-fine-pitch hybrid substrates with sizes exceeding wafer-scale formed by stitching together known-good substrates of smaller sizes (i.e., substrate units 120) using interconnect bridges. This is applicable for a wide range of applications, including HPC, data centers, AI, networking, mobiles, 5G/RF, and power electronics. By using the substrate units and the bridge structures, more dies (including the high-power dies 100 and the lower-power dies 106) can be mounted closely, without the need for a single, large, high-layer-count, fine-pitch laminate substrate which is difficult to fabricate at high yields.

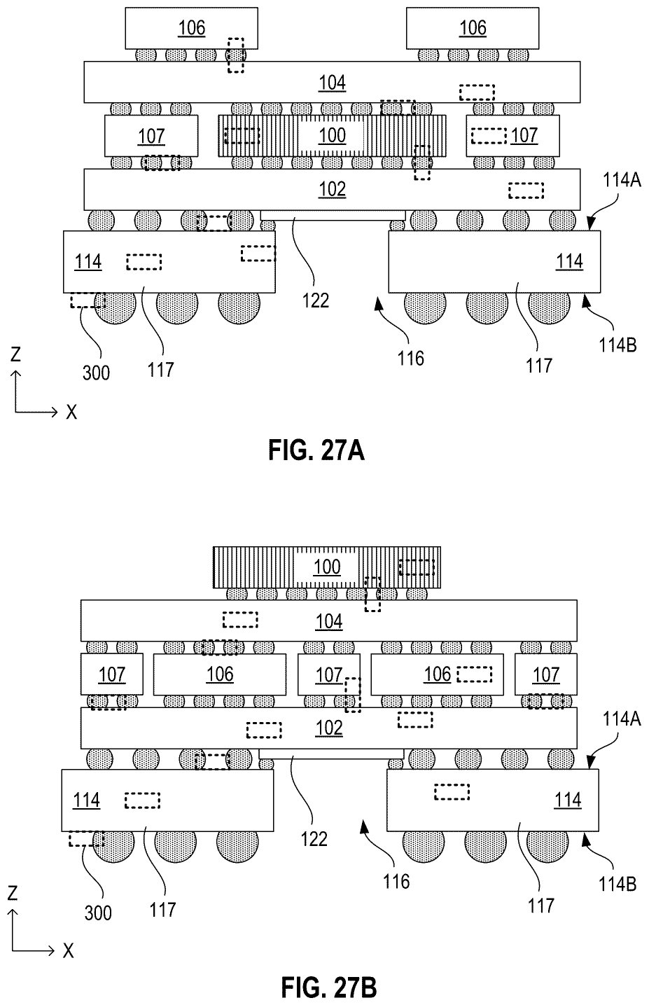

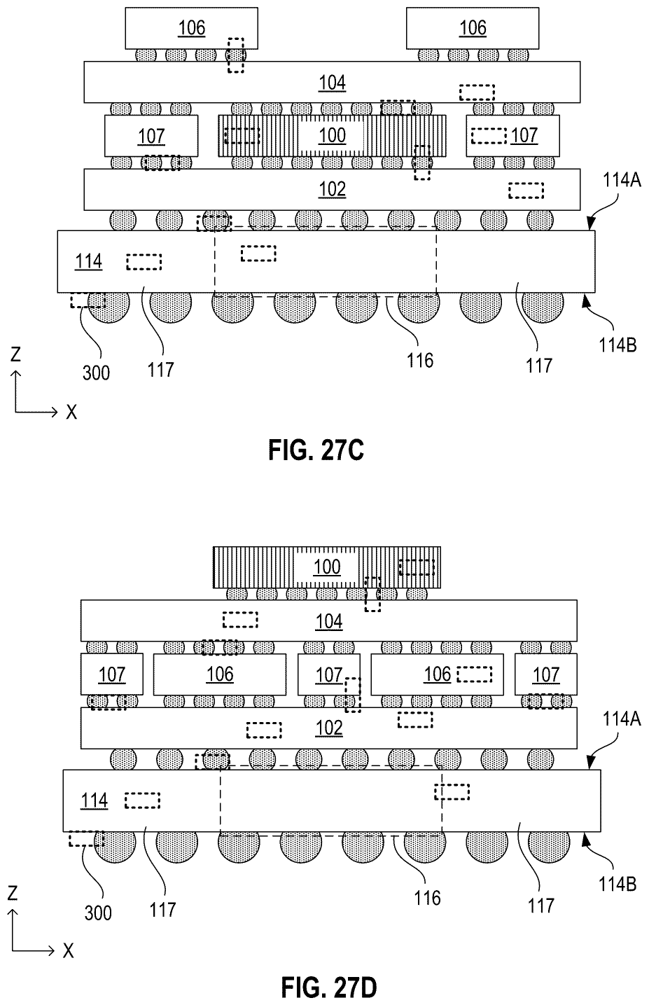

Referring to FIGS. 27A to 27D, in some embodiments, the 3D IC structures can include at least an electronic device 300 entirely or partially embedded in or mounted on the substrate structure 114, the first interposer 102, the high-power die 100, the second interposer 104, the lower-power die 106, and/or the bridge die 107 connecting the first interposer 102 and the second interposer 104. FIGS. 27A and 27B show 3D IC structure examples containing substrate structures 114 interconnected by a bridge structure 122. The available locations for the electronic devices 300 are labeled with dashed lines in these figures. The electronic devices 300 can include a fully integrated voltage regulator, a voltage regulator, a voltage driver, magnetics, a transformer, an inductor, a capacitor, an integrated passive device, or a combination thereof to enable vertical power delivery for applications such as HPC, data centers AI and other high-performance applications.

The foregoing outlines structures of several embodiments so that those skilled in the art may better understand the aspects of the present disclosure. Those skilled in the art should appreciate that they may readily use the present disclosure as a basis for designing or modifying other operations and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A three dimensional (3D) integrated circuit package, comprising:
a substrate structure having a first surface and a second surface opposite to the first surface;
a high-power die over the substrate structure;
a lower-power die over the high-power die;
a first interposer between the first surface of the substrate structure and the high-power die; and
a second interposer between the high-power die and the lower-power die,
wherein the substrate structure comprises a thermal enhancement portion located under the high-power die, and at least one of a thermal conductivity or a geometry of the thermal enhancement portion is different from other portions of the substrate structure.

2. The package of claim 1, wherein the thermal enhancement portion comprises a recess depressed from the second surface of the substrate structure, and a depth of the recess is at least 50% of a thickness of the other portion of the substrate structure.

3. The package of claim 1, wherein the thermal enhancement portion comprises an opening allowing a fluid to rise above the first surface of the substrate structure through the opening.

4. The package of claim 1, wherein the thermal enhancement portion comprises an opening filled with a high-thermal-conductivity material, and a top surface and a bottom surface of the high-thermal-conductivity material is coplanar to the first surface and the second surface of the substrate structure, respectively.

5. The package of claim 1, wherein the substrate structure comprises a plurality of substrate units physically separated from each other, and the thermal enhancement portion comprises a bridge structure configured to electrically or optically connect adjacent substrate units.

6. The package of claim 5, wherein the bridge structure comprises a bridge interposer substantially leveled with the adjacent substrate units, a silicon bridge structure connecting surfaces of the adjacent substrate units which constitute the first surface of the substrate structure, a flexible printed circuit connecting same or opposite surfaces of adjacent substrate units, or combinations thereof.

7. The package of claim 5, wherein from a top view perspective, the thermal enhancement portion further comprises a channel between adjacent substrate units allowing a fluid to rise above the first surface of the substrate structure through the channel.

8. The package of claim 1, wherein thermal conductivities of the first interposer and the second interposer are substantially greater than about 1,500 W/m·K.

9. The package of claim 1, further comprising:
an organic coating covering a plurality of exposed surfaces of the substrate structure, the lower-power die, the high-power die, the first interposer, the second interposer, and a sidewall of the substrate structure defining the opening.

10. A three dimensional (3D) integrated circuit package, comprising:
a substrate structure having a first surface and a second surface opposite to the first surface;
a lower-power die over the substrate structure;
a first high-power die over the lower-power die;
a first interposer between the first surface of the substrate structure and the lower-power die; and
a second interposer between the first high-power die and the lower-power die,
wherein the substrate structure comprises a thermal enhancement portion located under the first high-power die, and at least one of a thermal conductivity or a geometry of the thermal enhancement portion is different from other portions of the substrate structure.

11. The package of claim 10, wherein the first high-power die is a monolithic integrated circuit device comprising a plurality of cooling fins on a backside of the first high-power die.

12. The package of claim 10, wherein a first portion of the second interposer projectively under the first high-power die has a first thermal conductivity greater than a second thermal conductivity of a second portion of the second interposer not projectively under the first high-power die.

13. The package of claim 10, wherein a thermal conductivity of the first interposer is greater than a thermal conductivity of the second interposer.

14. The package of claim 10, wherein a thermal conductivity of the first interposer is equal to or lower than a thermal conductivity of the second interposer.

15. The package of claim 10, wherein a planar area of the second interposer is smaller than a planar area of the first interposer.

16. The package of claim 10, wherein the thermal enhancement portion comprises an opening filled with a high-thermal-conductivity material, a top surface and a bottom surface of the high-thermal-conductivity material is coplanar to the first surface and the second surface of the substrate structure, respectively.

17. The package of claim 10, further comprising:
at least a third interposer between the first interposer and the second interposer;
at least a second high-power die between the third interposer and the second interposer; and
at least a plurality of bridge dies next to the second high-power die or the lower-power die.

18. A substrate structure, comprising:
a plurality of substrate units separated from each other; and
a bridge structure configured to electrically connect adjacent substrate units, wherein the bridge structure comprises a first side and a second side opposite to the first side, at least one of the first side or the second side is electrically connected to adjacent substrate units or an integrated circuit through micro bumps or an interconnect layer.

19. The substrate structure of claim 18, wherein from a top view perspective, a length of the bridge structure is smaller than a length of each of the substrate units.

20. The substrate structure of claim 18, wherein the bridge structure further comprises:
interconnect layers on the first side and the second side; and
through vias traversing a thickness of the bridge structure and connecting the interconnect layers.
